(19) United States
(12) Patent Application Publication
(10) Pub. No.: US 2025/0318411 A1
(43) Pub. Date: Oct. 9, 2025

(54) DISPLAY DEVICE, METHOD OF MANUFACTURING THE SAME, AND ELECTRONIC DEVICE

(71) Applicant: Samsung Display Co., LTD., Yongin-si (KR)

(72) Inventors: PIL SOON HONG, Yongin-si (KR); SIKWANG KIM, Yongin-si (KR); SANGHYUN YUN, Yongin-si (KR); JAEHUN LEE, Yongin-si (KR); YANG-HO JUNG, Yongin-si (KR); Giheon CHOI, Yongin-si (KR)

(21) Appl. No.: 19/010,580

(22) Filed: Jan. 6, 2025

(30) Foreign Application Priority Data
Apr. 4, 2024 (KR) 10-2024-0046069

(51) Int. Cl. H10K 59/80; H10K 59/12

(52) U.S. Cl. CPC H10K 59/879; H10K 59/1201; H10K 59/8792

(57) ABSTRACT

A display device includes: a light emitting element layer including a light emitting element configured to emit light; an optical pattern disposed on the light emitting element layer and configured to change a path of the light emitted from the light emitting element; a cover layer covering the optical pattern and having a first refractive index; a light transmitting layer disposed on the cover layer, having a second refractive index different from the first refractive index, and defining openings each exposing a portion of the cover layer; and light blocking patterns disposed within the openings on the cover layer and overlapping both the optical pattern and the light emitting element in a plan view.

This application claims priority to Korean Patent Application No. 10-2024-0046069, filed on Apr. 4, 2024, and all the benefits accruing therefrom under 35 U.S.C. § 119, the content of which in its entirety is herein incorporated by reference.

### BACKGROUND

### 1. Field

Embodiments relate to a display device, a method of manufacturing the display device, and an electronic device including the display device. More particularly, embodiments relate to a display device which controls a viewing angle, a method of manufacturing the display device, and an electronic device including the display device.

### 2. Description of the Related Art

A display device is a device that displays an image and includes a display area for displaying an image. Recently, demand for a display device, in which a viewing angle of an image displayed in a display area is controlled, is increasing.

For example, the display device is frequently used in public places, and in this case, the viewing angle of the image displayed in the display area may be desired to be limited so that people around the user cannot recognize the image displayed in the display area. For another example, the viewing angle of the image displayed in a display area of a vehicle display may be desired. Accordingly, a display device capable of controlling the viewing angle is being researched.

### SUMMARY

Embodiments provide a display device which controls a viewing angle and has improved light efficiency.

Embodiments also provide a method of manufacturing the display device.

Embodiments also provide an electronic device including the display device.

Additional features of the invention will be set forth in the description which follows, and in part will be apparent from the description, or may be learned by practice of the invention.

A display device according to an embodiment includes: a light emitting element layer including a light emitting element configured to emit light; an optical pattern disposed on the light emitting element layer and configured to change a path of the light emitted from the light emitting element; a cover layer covering the optical pattern and having a first refractive index; a light transmitting layer disposed on the cover layer, having a second refractive index different from the first refractive index, and defining openings each exposing a portion of the cover layer; and light blocking patterns disposed within the openings on the cover layer and overlapping the optical pattern in a plan view.

In an embodiment, the first refractive index may be greater than the second refractive index.

In an embodiment, the cover layer may include a plurality of lens patterns repeatedly arranged.

In an embodiment, the lens patterns may be located on the path of the light changed by the optical pattern.

In an embodiment, the light transmitting layer may cover the lens patterns.

In an embodiment, the optical pattern may be disposed between the lens patterns in the plan view.

In an embodiment, the light blocking patterns and the lens patterns may be alternately arranged with each other.

In an embodiment, the optical pattern may include reflective patterns including a reflective material and configured to reflect the light emitted from the light emitting element.

In an embodiment, the display device may further include an insulating pattern layer, which is entirely covered by the cover layer and the reflective patterns and has a third refractive index greater than the second refractive index.

In an embodiment, the insulating pattern layer and the cover layer may include a same material as each other. The first refractive index and the third refractive index may be equal to each other.

In an embodiment, the insulating pattern layer may define engraved patterns therein. The reflective patterns may be disposed within the engraved patterns.

In an embodiment, the cover layer may be disposed to fill an empty space of the engraved patterns in which the reflective patterns are disposed.

In an embodiment, the optical pattern may include scattering patterns including scatterers configured to scatter the light emitted from the light emitting element.

A method of manufacturing a display device according to an embodiment includes: forming a light emitting element layer including a light emitting element configured to emit light on a substrate; forming an optical pattern configured to change a path of the light emitted from the light emitting element on the light emitting element layer; forming a cover layer covering the optical pattern and having a first refractive index; forming a light transmitting layer having a second refractive index different from the first refractive index and defining openings each exposing a portion of the cover layer on the cover layer; and forming light blocking patterns overlapping the optical pattern in a plan view within the openings on the cover layer.

In an embodiment, the first refractive index may be greater than the second refractive index.

In an embodiment, the forming of the cover layer may include forming a preliminary layer having the first refractive index, and patterning the preliminary layer to form a plurality of lens patterns repeatedly arranged. The light transmitting layer may be formed to cover the lens patterns.

In an embodiment, the method may further include, before the forming of the optical pattern, forming an insulating pattern layer having a third refractive index greater than the second refractive index and defining engraved patterns therein on the light emitting element layer. The forming of the optical pattern may include forming the optical pattern within the engraved patterns by forming a reflective layer including a reflective material on the insulating pattern layer and patterning the reflective layer.

In an embodiment, the insulating pattern layer and the cover layer may be formed of the same material. The first refractive index and the third refractive index may be equal to each other.

In an embodiment, the cover layer may be formed to cover both the insulating pattern layer and the optical pattern.

In an embodiment, the forming of the optical pattern may include forming a scattering layer including scatterers on the light emitting element layer and patterning the scattering layer.

An electronic device according to an embodiment includes: a display device; and a power supply configured to provide power to the display device. The display device includes: a light emitting element layer including a light emitting element configured to emit light; an optical pattern disposed on the light emitting element layer and configured to change a path of the light emitted from the light emitting element; a cover layer covering the optical pattern and having a first refractive index; a light transmitting layer disposed on the cover layer, having a second refractive index different from the first refractive index, and defining openings each exposing a portion of the cover layer; and light blocking patterns disposed within the openings on the cover layer and overlapping the optical pattern in a plan view.

The display device according to embodiments may include the light transmitting layer disposed on the light emitting element layer and defining the openings, and the light blocking patterns disposed within the openings. The light blocking patterns may control or limit a viewing angle of light emitted from the light emitting element layer.

In addition, the display device may include the optical pattern configured to change the path of the light emitted from the light emitting element and the cover layer covering the optical pattern and including the lens patterns. The light blocking patterns may be disposed on the optical pattern and may overlap the optical pattern in a plan view. The refractive index of the light transmitting layer may be less than the refractive index of the cover layer, and the light transmitting layer may be disposed on the cover layer to form an interface with the lens patterns of the cover layer.

Accordingly, an incident light emitted from the light emitting element and traveling in a front direction toward the light blocking patterns may be provided to the optical pattern before arriving at the light blocking patterns. A path of the incident light may be changed by the optical pattern, and thus, the incident light may travel in a direction other than the front direction. Accordingly, light obtained by changing the path of the incident light by the optical pattern may travel between the light blocking patterns.

In addition, the light obtained by changing the path of the incident light by the optical pattern may be provided at an interface between the light transmitting layer and the lens patterns. The light provided at the interface may be refracted due to a difference in refractive indices between the light transmitting layer and the cover layer and/or shapes of the lens patterns and may travel in the front direction again. That is, a refracted light obtained by the light obtained by changing the path of the incident light by the optical pattern refracting at the interface may travel in the front direction and may be emitted to the outside through the light transmitting layer. Therefore, according to embodiments, a loss of the light, which is emitted from the light emitting element and travels in the front direction, due to the light blocking patterns may be effectively reduced or prevented. Accordingly, a front light transmittance of the display device may be improved, and a light efficiency of the display device may be effectively improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a plan view illustrating a display device according to an embodiment.

FIG. 2 is an enlarged view illustrating a pixel area of the display device of FIG. 1.

FIG. 3 is a cross-sectional view illustrating an example taken along line I-I′ of FIG. 2.

FIGS. 4 to 11 are views illustrating a method of manufacturing a display device according to an embodiment.

FIG. 12 is a cross-sectional view illustrating another example taken along line I-I′ of FIG. 2.

FIGS. 13 to 16 are views illustrating a method of manufacturing a display device according to an embodiment.

FIG. 17 is a cross-sectional view illustrating still another example taken along line I-I′ of FIG. 2.

FIGS. 18 to 21 are views illustrating a method of manufacturing a display device according to an embodiment.

FIG. 22 is a cross-sectional view illustrating yet another example taken along line I-I′ of FIG. 2.

FIGS. 23 to 26 are views illustrating a method of manufacturing a display device according to an embodiment.

FIG. 27 is a cross-sectional view illustrating still another example taken along line I-I′ of FIG. 2.

FIG. 28 is a block diagram illustrating an electronic device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, a reference number may indicate a singular element or a plurality of the element. For example, a reference number labeling a singular form of an element within the drawing figures may be used to reference a plurality of the singular element within the text of specification.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

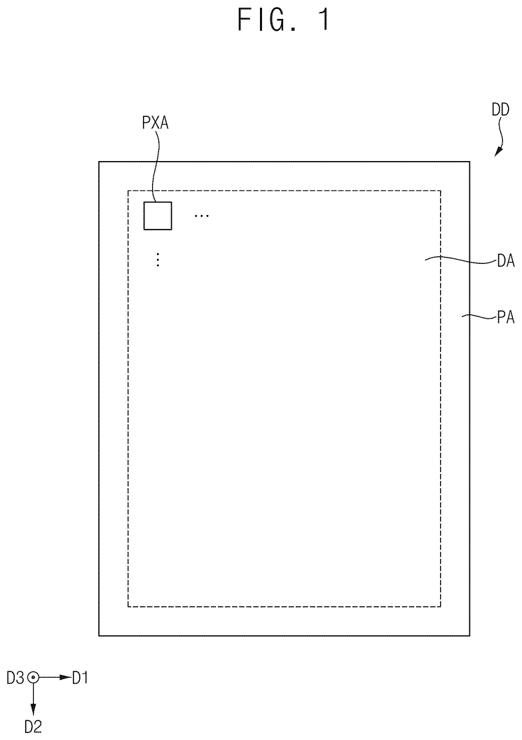

Illustrative, non-limiting embodiments will be more clearly understood from the following detailed description in conjunction with the accompanying drawings. FIG. 1 is a plan view illustrating a display device according to an embodiment.

Referring to FIG. 1, a display device DD according to an embodiment may be divided into a display area DA and a peripheral area PA. The display area DA may display an image, and the peripheral area PA may be located around the display area DA. For example, the peripheral area PA may surround the display area DA.

In an embodiment, the display device DD may have a rectangular shape in a plan view. However, embodiments are not limited thereto, and the display device DD may have various shapes in a plan view. In this case, a plane on which a display surface of the display device DD is disposed may be defined by a first direction D1 and a second direction D2 crossing the first direction D1. For example, the first direction D1 and the second direction D2 may be perpendicular to each other. A third direction D3 may be perpendicular to the plane. That is, the third direction D3 may be a normal direction of the plane. Hereinafter, the third direction D3 may be referred to as a “front direction” or a “thickness direction” of the display device DD. As used herein, the “plan view” is a view in the thickness direction of the display device DD.

The display device DD may include a plurality of pixel areas PXA disposed in the display area DA. For example, the pixel areas PXA may be disposed in a matrix form along the first direction D1 and the second direction D2.

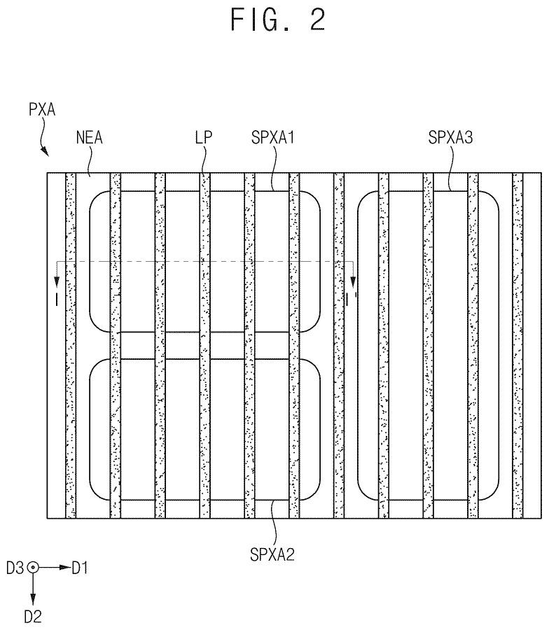

FIG. 2 is an enlarged view illustrating a pixel area of the display device of FIG. 1.

Referring to FIGS. 1 and 2, each of the pixel areas PXA may include first to third sub-pixel areas SPXA1, SPXA2, and SPXA3 which emit light of different colors and a non-emission area NEA surrounding the first to third sub-pixel areas SPXA1, SPXA2, and SPXA3. For example, the first sub-pixel area SPXA1 may emit red light, the second sub-pixel area SPXA2 may emit green light, and the third sub-pixel area SPXA3 may emit blue light. However, embodiments are not limited thereto, and the first to third sub-pixel areas SPXA1, SPXA2, and SPXA3 may be combined so that each of the pixel areas PXA emits yellow, cyan, and magenta lights in another embodiment.

In an embodiment, an arrangement structure of the first to third sub-pixel areas SPXA1, SPXA2, and SPXA3 may be an S-stripe structure. For example, the first sub-pixel area SPXA1 and the second sub-pixel area SPXA2 may be disposed in a first column, and the third sub-pixel area SPXA3 may be disposed in a second column adjacent to the first column. In this case, one side of each of the first sub-pixel area SPXA1 and the second sub-pixel area SPXA2 may face a long side of the third sub-pixel area SPXA3. However, this is an example, and the arrangement of the first to third sub-pixel areas SPXA1, SPXA2, and SPXA3 in a plan view is not limited thereto.

FIG. 2 illustrates that each of the pixel areas PXA includes the first to third sub-pixel areas SPXA1, SPXA2, and SPXA3, but embodiments are not limited thereto. For another example, each of the pixel areas may include two sub-pixel areas or four or more sub-pixel areas.

In an embodiment, the display device DD may include light blocking patterns LP. The light blocking patterns LP may extend in the second direction D2. In an embodiment, the light blocking patterns LP may be arranged side by side with each other in a plan view. For example, the light blocking patterns LP may be spaced apart from each other in the first direction D1. In other words, the light blocking patterns LP may be parallel to each other. However, an arrangement of the light blocking patterns LP is not limited thereto.

The light blocking patterns LP may control or limit a viewing angle of light emitted from each of the first to third sub-pixel areas SPXA1, SPXA2, and SPXA3. In an embodiment, the light blocking patterns LP may be disposed to overlap the first to third sub-pixel areas SPXA1, SPXA2, and SPXA3. As used herein, the “viewing angle” is measured with respect to the third direction DR3. However, the embodiments are not limited thereto. For another example, the light blocking patterns LP may be disposed to be spaced apart from the first to third sub-pixel areas SPXA1, SPXA2, and SPXA3 and overlap the non-emission area NEA. In other words, the light blocking patterns LP may be disposed between the first to third sub-pixel areas SPXA1, SPXA2, and SPXA3. In addition, the light blocking patterns LP may overlap at least one of the first to third sub-pixel areas SPXA1, SPXA2, and SPXA3 and may be spaced apart from at least one of the others.

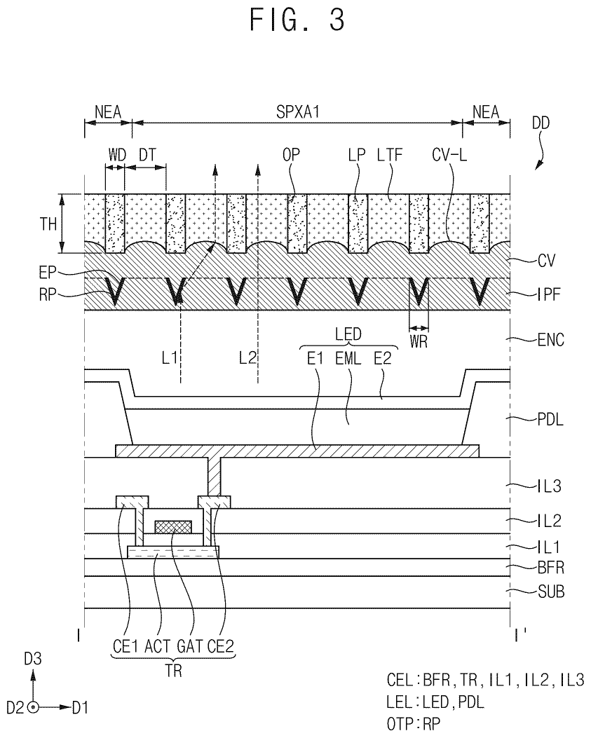

FIG. 3 is a cross-sectional view illustrating an example taken along line I-I′ of FIG. 2.

in FIG. 3, only a cross-sectional structure of the first sub-pixel area SPXA1 is illustrated for convenience of illustration and description. A cross-sectional structure of each of the second sub-pixel area SPXA2 and the third sub-pixel area SPXA3 may be substantially the same as the cross-sectional structure of the first sub-pixel area SPXA1. Therefore, a description of the cross-sectional structure of each of the second sub-pixel area SPXA2 and the third sub-pixel area SPXA3 is replaced with the description of the cross-sectional structure of the first sub-pixel area SPXA1.

Referring to FIG. 3, the display device DD may include a substrate SUB, a circuit element layer CEL, a light emitting element layer LEL, an encapsulation layer ENC, an insulating pattern layer IPF, an optical pattern OTP, a cover layer CV, a light transmitting layer LTF, and the light blocking patterns LP.

The substrate SUB may include a transparent or opaque material. In an embodiment, examples of materials that can be used as the substrate SUB may include glass, quartz, plastic, or the like. These may be used alone or in combination with each other.

The circuit element layer CEL may be disposed on the substrate SUB. The circuit element layer CEL may include a buffer layer BFR, a driving element TR, and first to third insulating layers IL1, IL2, and IL3. The driving element TR may include an active pattern ACT, a gate electrode GAT, a first connection electrode CE1, and a second connection electrode CE2.

The buffer layer BFR may be disposed on the substrate SUB. The buffer layer BFR may prevent or reduce diffusion of impurities such as oxygen, moisture, or the like to an upper portion of the substrate SUB through the substrate SUB. The buffer layer BFR may include an inorganic insulating material. Examples of the inorganic insulating material that can be used as the buffer layer BFR may include silicon oxide, silicon nitride, silicon oxynitride, or the like. These may be used alone or in combination with each other.

The active pattern ACT may be disposed on the buffer layer BFR. In an embodiment, the active pattern ACT may include a silicon semiconductor material or an oxide semiconductor material. Examples of the silicon semiconductor material that can be used as the active pattern ACT may include amorphous silicon, polycrystalline silicon, or the like. Examples of the oxide semiconductor material that can be used as the active pattern ACT may include InGaZnO (IGZO), InSnZnO (ITZO), or the like.

In an embodiment, the first insulating layer IL1 may be disposed on the buffer layer BFR. The first insulating layer IL1 may cover the active pattern ACT. In another embodiment, the first insulating layer IL1 may be disposed in a pattern shape on the active pattern ACT to expose a portion of the active pattern ACT. For example, the first insulating layer IL1 may be disposed on the active pattern ACT in a pattern shape to overlap the gate electrode GAT in a plan view. The first insulating layer IL1 may include an inorganic insulating material. Examples of inorganic insulating material that can be used as the first insulating layer IL1 may include silicon oxide, silicon nitride, silicon oxynitride, or the like. These may be used alone or in combination with each other.

The gate electrode GAT may be disposed on the first insulating layer IL1. In an embodiment, the gate electrode GAT may include a metal, an alloy, a conductive metal oxide, a transparent conductive material, or the like.

The second insulating layer IL2 may be disposed on the first insulating layer IL1. In an embodiment, the second insulating layer IL2 may cover the gate electrode GAT. The second insulating layer IL2 may include an inorganic insulating material. Examples of inorganic insulating material that can be used as the second insulating layer IL2 may include silicon oxide, silicon nitride, silicon oxynitride, or the like. These may be used alone or in combination with each other.

The first connection electrode CE1 and the second connection electrode CE2 may be disposed on the second insulating layer IL2. The first connection electrode CE1 and the second connection electrode CE2 may be electrically connected to the active pattern ACT through a contact hole defined or formed in the first insulating layer IL1 and the second insulating layer IL2. Each of the first connection electrode CE1 and the second connection electrode CE2 may include a metal, an alloy, a conductive metal oxide, a transparent conductive material, or the like.

The third insulating layer IL3 may be disposed on the second insulating layer IL2. The third insulating layer IL3 may cover the first connection electrode CE1 and the second connection electrode CE2. The third insulating layer IL3 may include an organic insulating material. Examples of organic insulating material that can be used as the third insulating layer IL3 may include photoresist, polyacryl-based resin, polyimide-based resin, polyamide-based resin, siloxane-based resin, acrylic-based resin, epoxy-based resin, or the like. These may be used alone or in combination with each other. The third insulating layer IL3 may have a single-layer structure or a multi-layer structure including a plurality of insulating layers.

The structure of the circuit element layer CEL described with reference to FIG. 3 is an example, and the structure of the circuit element layer CEL may be variously changed or modified.

The light emitting element layer LEL may be disposed on the circuit element layer CEL. The light emitting element layer LEL may include a pixel defining layer PDL and the light emitting element LED. The light emitting element LED may include a pixel electrode E1, an emission layer EML, and a common electrode E2. The light emitting element LED may be driven by the driving element TR to emit light.

The pixel electrode E1 may be disposed on the third insulating layer IL3. The pixel electrode E1 may be electrically connected to the driving element TR through a contact hole defined or formed in the third insulating layer IL3. In an embodiment, the pixel electrode E1 may include a metal, an alloy, a conductive metal oxide, a transparent conductive material, or the like.

Although not illustrated, in an embodiment, a third connection electrode and a fourth insulating layer may be further disposed between the third insulating layer IL3 and the pixel electrode E1. The third connection electrode may contact the first connection electrode CE1 or the second connection electrode CE2 and may include a metal, an alloy, a conductive metal oxide, a transparent conductive material, or the like. The fourth insulation layer may cover the third connection electrode and may include an organic insulating material. In this case, the pixel electrode E1 may contact the third connection electrode through a contact hole defined in the fourth insulating layer and may be electrically connected to the driving element TR through the third connection electrode.

The pixel defining layer PDL may be disposed on the third insulating layer IL3. The pixel defining layer PDL may define a pixel opening exposing a portion of the pixel electrode E1. The first sub-pixel area SPXA1 may be defined by the pixel opening. That is, the pixel defining layer PDL may be disposed in the non-emission area NEA. For example, the pixel defining layer PDL may have a grid shape in a plan view. In an embodiment, the pixel defining layer PDL may include an organic insulating material. Examples of organic insulating material that can be used as the pixel defining layer PDL may include photoresist, polyacrylic resin, polyimide resin, acrylic resin, or the like. These may be used alone or in combination with each other.

The emission layer EL may be disposed on the pixel electrode E1 in the pixel opening. The emission layer EL may include a material which emits light. For example, the emission layer EL may include an organic light emitting material. However, embodiments are not limited thereto, and the emission layer EL may include an inorganic light emitting material, a quantum dot, or the like in another embodiment.

In an embodiment, functional layers such as a hole injection layer, a hole transport layer, an electron transport layer, and an electron injection layer may be further disposed above and/or below the emission layer EL.

The common electrode E2 may be disposed on the emission layer EL. The common electrode E2 may include a conductive material such as a metal, an alloy, a conductive metal nitride, a conductive metal oxide, a transparent conductive material, or the like. The common electrode E2 may have a single-layer structure or a multi-layer structure including a plurality of conductive layers. In an embodiment, the common electrode E2 may continuously extend (or commonly disposed) over the plurality of pixel areas.

The encapsulation layer ENC may be disposed on the light emitting element layer LEL. The encapsulation layer ENC may cover the light emitting element LED. The encapsulation layer ENC may protect the light emitting element LED from external moisture, heat, shock, or the like. Although not illustrated, in an embodiment, the encapsulation layer ENC may include a first inorganic encapsulation layer, an organic encapsulation layer disposed on the first inorganic encapsulation layer, and a second inorganic encapsulation layer disposed on the organic encapsulation layer.

The insulating pattern layer IPF may be disposed on the encapsulation layer ENC. The insulating pattern layer IPF may define engraved patterns EP. The engraved patterns EP may be defined by being recessed from an upper surface of the insulating pattern layer IPF. That is, each of the engraved patterns EP may be defined by an inner side surface of the insulating pattern layer IPF.

In an embodiment, the engraved patterns EP may extend from the upper surface of the insulating pattern layer IPF to a point inside the insulating pattern layer IPF. In addition, in an embodiment, the engraved patterns EP may extend from the upper surface of the insulating pattern layer IPF to a lower surface of the insulating pattern layer IPF. FIG. 3 illustrates that a cross-sectional shape of each of the engraved patterns EP is an inverted triangle shape, but embodiments are not limited thereto.

The insulating pattern layer IPF may include an insulating material. For example, the insulating pattern layer IPF may include an organic insulating material having relatively high light transmittance. Examples of organic insulating materials that can be used as the insulating pattern layer IPF may include photoresist, polyacryl-based resin, polyimide-based resin, acrylic-based resin, or the like. These may be used alone or in combination with each other.

The insulating pattern layer IPF may have a first refractive index. For example, the insulating pattern layer IPF may be formed of an insulating material having the first refractive index. The first refractive index of the insulating pattern layer IPF may be about 1.6 or more. Specifically, the first refractive index of the insulating pattern layer IPF may be about 1.6 to about 1.7. However, embodiments are not limited thereto.

Although not illustrated, in an embodiment, additional functional layers may be disposed between the encapsulation layer ENC and the insulating pattern layer IPF. For example, a sensing layer for detecting an external touch may be disposed between the encapsulation layer ENC and the insulating pattern layer IPF.

The optical pattern OTP may be disposed on the encapsulation layer ENC. The optical pattern OTP may change a path of the light emitted from the light emitting element LED. For example, a path of some of the light emitted from the light emitting element LED that arrives at the optical pattern OTP may be changed by the optical pattern OTP.

In an embodiment, the optical pattern OTP may include reflective patterns RP. For example, the optical pattern OTP may be a set of the reflective patterns RP.

The reflective patterns RP may change the path of the some of the light emitted from the light emitting element LED that arrives at the reflective patterns RP. Specifically, light provided to the reflective patterns RP while traveling in the third direction D3 may be reflected by the reflective patterns RP to travel in a direction other than the third direction D3.

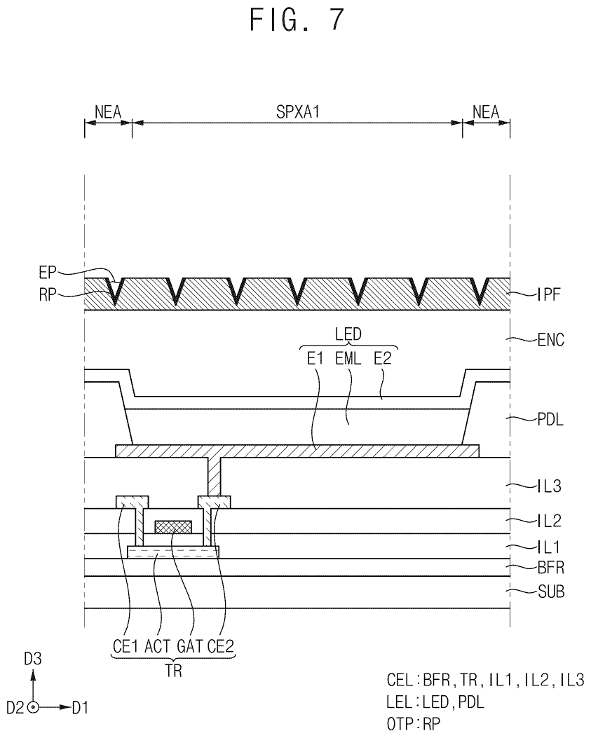

The reflective patterns RP may be disposed within the engraved patterns EP. For example, one of the reflective patterns RP may be disposed within a corresponding one of the engraved patterns EP. That is, the reflective patterns RP and the engraved patterns EP may correspond to each other one by one. In another embodiment, the reflective patterns RP may not be disposed on the upper surface of the insulating pattern layer IPF. In this case, a dummy portion (not illustrated) remaining after a process of forming the reflective patterns RP may be disposed on the upper surface of the insulating pattern layer IPF. The dummy portion may include the same material as the reflective patterns RP. However, embodiments are not limited thereto, and the dummy portion may be omitted in another embodiment. This will be described in more detail later with reference to FIG. 7.

The reflective patterns RP may include a reflective material. For example, the reflective patterns RP may include a metal material. Examples of the metal material that can be used as the reflective patterns RP may include silver (Ag), magnesium (Mg), aluminum (Al), platinum (Pt), palladium (Pd), gold (Au), nickel (Ni), neodymium (Nd), iridium (Ir), chromium (Cr), or the like. The reflective patterns RP may have a single-layer structure or a multi-layer structure including a plurality of conductive layers.

In an embodiment, a cross-sectional shape of each of the reflective patterns RP may be the same as the cross-sectional shape of each of the engraved patterns EP (e.g., inverted triangle shape, V-shape). Meanwhile, a shape of each of the reflective patterns RP illustrated in FIG. 3 is an example, and the shape may be variously changed or modified. For example, the shape of each of the reflective patterns RP may be variously changed or modified according to a shape of each of the engraved patterns EP.

The cover layer CV may be disposed on the insulating pattern layer IPF and the reflective patterns RP (i.e., the optical pattern OTP). The cover layer CV may cover the reflective patterns RP. For example, the cover layer CV may fill empty spaces of the engraved patterns EP in which the reflective patterns RP are disposed.

The cover layer CV may include an insulating material. For example, the cover layer CV may include an organic insulating material. Examples of organic insulating materials that can be used as the cover layer CV may include photoresist, polyacryl-based resin, polyimide-based resin, acrylic-based resin, or the like. These may be used alone or in combination with each other.

The cover layer CV may have a second refractive index. For example, the cover layer CV may be formed of an insulating material having the second refractive index. The second refractive index of the cover layer CV may be about 1.6 or more. Specifically, the second refractive index of the cover layer CV may be about 1.6 to about 1.7. However, embodiments are not limited thereto.

The cover layer CV and the insulating pattern layer IPF may include the same material as each other. For example, the cover layer CV and the insulating pattern layer IPF may be formed of the same material. That is, the second refractive index of the cover layer CV may be equal to the first refractive index of the insulating pattern layer IPF. Accordingly, a path of light may not be changed at an interface between the insulating pattern layer IPF and the cover layer CV. The interface between the insulating pattern layer IPF and the cover layer CV may correspond to the upper surface of the insulating pattern layer IPF.

The cover layer CV may include lens patterns CV-L. In an embodiment, the lens patterns CV-L may be defined by a concave-convex structure of an upper surface of the cover layer CV. For example, the cover layer CV including the lens patterns CV-L may be formed by applying a preliminary layer on the insulating pattern layer IPF and the optical pattern OTP, and patterning the preliminary layer using a half-tone mask or the like. However, embodiments are not limited thereto. Each of the lens patterns CV-L may include a spherical lens or an aspherical lens in another embodiment.

The lens patterns CV-L may be repeatedly arranged. For example, the lens patterns CV-L may be repeatedly arranged along the first direction D1. In a plan view, the reflective patterns RP (i.e., the optical pattern OTP) may be disposed between the lens patterns CV-L. That is, the lens patterns CV-L may not overlap the reflective patterns RP (i.e., the optical pattern OTP) in the third direction D3. For example, the lens patterns CV-L and the reflective patterns RP may be alternately arranged with each other.

The lens patterns CV-L may be located on the path of the light changed by the reflective patterns RP (i.e., the optical pattern OTP). That is, a reflected light obtained by the light emitted from the light emitting element LED being reflected by the reflective patterns RP may be provided to the lens patterns CV-L.

The light transmitting layer LTF may be disposed on the cover layer CV. The light transmitting layer LTF may define openings OP each exposing a portion of the cover layer CV. Each of the openings OP may be defined by an inner side surface of the light transmitting layer LTF. In other words, the openings OP may penetrate the light transmitting layer LTF in the third direction D3. In an embodiment, the light transmitting layer LTF may have a grid shape in a plan view.

The light transmitting layer LTF may be disposed corresponding to positions where the lens patterns CV-L are disposed. The light transmitting layer LTF may cover the lens patterns CV-L. That is, the openings OP of the light transmitting layer LTF may not expose the lens patterns CV-L and may expose portions of the cover layer CV other than the lens patterns CV-L. For example, the lens patterns CV-L and the openings OP may be alternately arranged with each other. That is, the lens patterns CV-L and the openings OP may not overlap each other in the third direction D3. Accordingly, the interface between the light transmitting layer LTF and the cover layer CV may be an interface between the light transmitting layer LTF and the lens patterns CV-L.

The light transmitting layer LTF may include an insulating material. For example, the light transmitting layer LTF may include an organic insulating material having relatively high light transmittance. Examples of organic insulating materials that can be used as the light transmitting layer LTF may include photoresists, polyacrylic resins, polyimide resins, acrylic resins, or the like. These may be used alone or in combination with each other.

The light transmitting layer LTF may have a third refractive index. For example, the light transmitting layer LTF may be formed of an insulating material having the third refractive index. The third refractive index of the light transmitting layer LTF may be less than about 1.6. Specifically, the third refractive index of the light transmitting layer LTF may be about 1.45 to about 1.53. However, embodiments are not limited thereto.

The third refractive index of the light transmitting layer LTF may be different from the second refractive index of the cover layer CV. For example, the third refractive index of the light transmitting layer LTF may be less than the second refractive index of the cover layer CV. Accordingly, light may be refracted at the interface between the light transmitting layer LTF and the cover layer CV (i.e., the interface between the light transmitting layer LTF and the lens patterns CV-L) due to a difference in refractive indices between the light transmitting layer LTF and the cover layer CV.

Specifically, the reflected light reflected by the reflective patterns RP and provided to the lens patterns CV-L may be refracted at the interface between the light transmitting layer LTF and the lens patterns CV-L and may travel in the third direction D3. That is, a refracted light obtained by the reflected light refracting at the interface between the light transmitting layer LTF and the lens patterns CV-L may travel in the third direction D3 and may be provided to the light transmitting layer LTF.

The light blocking patterns LP may be disposed on the cover layer CV. The light blocking patterns LP may be disposed within the openings OP defined in the light transmitting layer LTF. Accordingly, the light transmitting layer LTF may be disposed between the light blocking patterns LP. The light blocking patterns LP may expose an upper surface of the light transmitting layer LTF.

As the light blocking patterns LP are disposed within the openings OP, the light blocking patterns LP and the lens patterns CV-L may be alternately arranged with each other. For example, the light blocking patterns LP and the lens patterns CV-L may not overlap each other in the third direction D3.

The light blocking patterns LP may overlap the reflective patterns RP (i.e., the optical pattern OTP) in a plan view. For example, one of the light blocking patterns LP may overlap a corresponding one of the reflective patterns RP in the third direction D3. That is, the light blocking patterns LP and the reflective patterns RP may correspond to each other one by one.

In an embodiment, light emitted from the light emitting element LED may be incident on the light blocking patterns LP or may pass through between the light blocking patterns LP. The light passing through between the light blocking patterns LP may be emitted to the outside due to a high light transmittance of the light transmitting layer LTF. Most of the light incident on the light blocking patterns LP may be reflected or absorbed by the light blocking patterns LP. For example, most of light traveling in a direction inclined at a cut-off angle with respect to the third direction D3 may be blocked by the light blocking patterns LP, and thus, the light blocking patterns LP may control or limit the viewing angle of the light emitted from the light emitting element LED.

For example, a range of the cut-off angle may be controlled by adjusting a thickness TH of each of the light blocking patterns LP, a width WD of each of the light blocking patterns LP, and/or a distance DT between two of the adjacent light blocking patterns LP.

The light blocking patterns LP may include various materials blocking light emitted from the light emitting element LED. Examples of materials that can be used as the light blocking patterns LP may include a black pigment, a black dye, carbon black, chrome, or the like. These may be used alone or in combination with each other. Another example of materials that can be used as the light blocking patterns LP may include molybdenum-tantalum oxide (MTO).

Hereinafter, with reference to a first incident light L1 and a second incident light L2 illustrated in FIG. 3, a path change of light by the reflective patterns RP (i.e., the optical pattern OTP) and the lens patterns CV-L of the cover layer CV will be described.

The first incident light L1 may be light that is emitted from the light emitting element LED and travels in the third direction D3 toward the light blocking patterns LP. The second incident light L2 may be light that is emitted from the light emitting element LED and travels in the third direction D3 toward between the light blocking patterns LP (i.e., toward the light transmitting layer LTF).

As illustrated in FIG. 3, the first incident light L1 may be provided to one of the reflective patterns RP before arriving at the light blocking patterns LP. That is, the reflective pattern RP may be located on the path of the first incident light L1. The first incident light L1 may be reflected by the reflective pattern RP and may travel in a direction other than the third direction D3. That is, the path of the first incident light L1 may be changed by the reflective pattern RP. For this, in an embodiment, a shape and an area of the reflective pattern RP may be the same as a shape and an area of a corresponding light blocking pattern LP such that the reflective pattern RP completely overlaps the corresponding light blocking pattern LP in a plan view. For example, a width WR of the reflective pattern RP may be the same as the width WD of the corresponding light blocking pattern LP measured in the same direction (e.g., the first direction DR1.)

A reflected light obtained by the first incident light L1 being reflected by the reflective pattern RP may be provided to one of the lens patterns CV-L. That is, the reflected light may be provided to the interface between the light transmitting layer LTF and the lens patterns CV-L. The reflected light may be refracted at the interface due to the difference in refractive indices between the light transmitting layer LTF and the cover layer CV and/or shapes of the lens patterns CV-L and may travel in the third direction D3 again. That is, a refracted light obtained by the reflected light being refracted at the interface may travel in the third direction D3 and may be emitted to the outside through the light transmitting layer LTF.

As a result, the path of the first incident light L1 traveling in the third direction D3 toward the light blocking patterns LP may be changed by the reflective patterns RP (i.e., the optical pattern OTP) and the lens patterns CV-L. Therefore, the first incident light L1 may not be blocked by the light blocking patterns LP and may be emitted to the outside through the light transmitting layer LTF while traveling in the third direction D3. In other words, the first incident light L1 may not be lost.

Meanwhile, the second incident light L2 may not be affected by the reflective patterns RP. That is, the reflective patterns RP may not be located on a path of the second incident light L2. For example, the second incident light L2 may travel between the reflective patterns RP. Accordingly, the second incident light L2 may travel in the third direction D3 without substantially changing the path and may be emitted to the outside through the light transmitting layer LTF.

When the light blocking patterns LP are disposed on the light emitting element layer LEL for controlling the viewing angle, most of the light traveling in the third direction D3 toward the light blocking patterns LP may be blocked by the light blocking patterns LP. In other words, most of the light traveling in the third direction D3 toward the light blocking patterns LP may be lost. Accordingly, a front light transmittance of the display device DD may be reduced, and a light efficiency of the display device DD may be reduced.

The display device DD according to an embodiment may include the reflective patterns RP (i.e., the optical pattern OTP) changing the path of the light emitted from the light emitting element LED, and the cover layer CV covering the reflective patterns RP and including the lens patterns CV-L. In addition, the light blocking patterns LP may be disposed on the reflective patterns RP and may overlap the reflective patterns RP in a plan view. In addition, the refractive index of the light transmitting layer LTF may be less than the refractive index of the cover layer CV, and the light transmitting layer LTF may be disposed on the cover layer CV to form the interface with the lens patterns CV-L of the cover layer CV.

Accordingly, an incident light emitted from the light emitting element LED and traveling in the third direction D3 toward the light blocking patterns LP may be provided to the reflective patterns RP (i.e., the optical pattern OTP) before arriving at the light blocking patterns LP. The incident light provided to the reflective patterns RP may be reflected by the reflective patterns RP and may travel in a direction other than the third direction D3. Accordingly, a reflected light obtained by the incident light being reflected by the reflective patterns RP may travel between the light blocking patterns LP.

In addition, the reflected light may be provided at the interface between the light transmitting layer LTF and the lens patterns CV-L. The reflected light provided at the interface may be refracted due to the difference in refractive indices between the light transmitting layer LTF and the cover layer CV and/or the shapes of the lens patterns CV-L and may travel in the third direction D3 again. That is, a refracted light obtained by the reflected light refracting at the interface may travel in the third direction D3 and may be emitted to the outside through the light transmitting layer LTF. Therefore, according to embodiments, a loss of the light, which is emitted from the light emitting element LED and travels in the third direction D3, due to the light blocking patterns LP may be reduced or prevented. Accordingly, the front light transmittance of the display device DD may be improved, and the light efficiency of the display device DD may be effectively improved.

In addition, according to embodiments, since the loss of the light traveling in the third direction D3 due to the light blocking patterns LP may be reduced or prevented, an area through which light is transmitted in the third direction D3 may be designed smaller. That is, the distance DT between two of the adjacent light blocking patterns LP may be reduced. Accordingly, the thickness TH of each of the light blocking patterns LP for obtaining a desired effect of controlling the viewing angle may also be reduced. Accordingly, a process for forming the light blocking patterns LP and the light transmitting layer LTF may be simplified, and structures of the light blocking patterns LP and the light transmitting layer LTF may be simplified.

In an embodiment, the distance DT between two of the adjacent light blocking patterns LP may be about 10 micrometers or less. Specifically, the distance DT between two of the adjacent light blocking patterns LP may be about 4 micrometers to about 10 micrometers. If the distance DT between two of the adjacent light blocking patterns LP is less than about 4 micrometers, the light efficiency of the display device DD may be somewhat reduced.

In addition, in an embodiment, the thickness TH of each of the light blocking patterns LP may be about 15 micrometers or less. Specifically, the thickness TH of each of the light blocking patterns LP may be about 5 micrometers to about 15 micrometers. If the thickness TH of each of the light blocking patterns LP is less than about 5 micrometers, it may be difficult to obtain the desired effect of controlling the viewing angle.

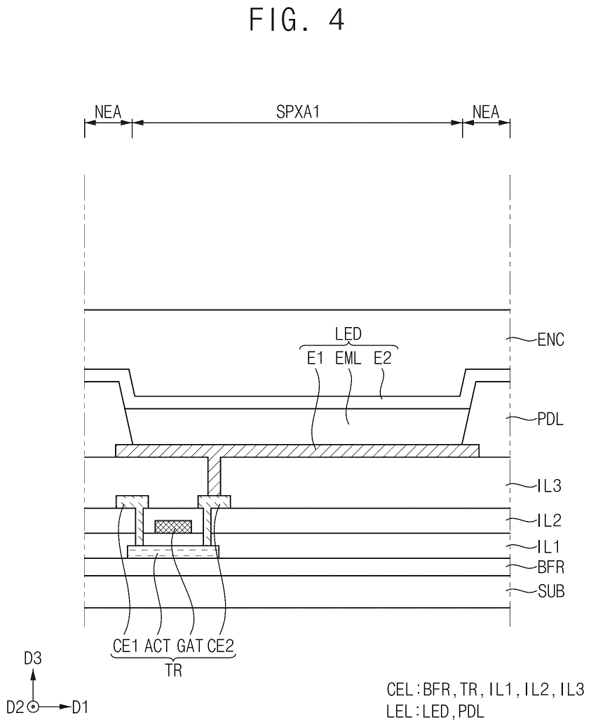

FIGS. 4 to 11 are views illustrating a method of manufacturing a display device according to an embodiment.

Specifically, FIGS. 4 to 11 are views for describing a method of manufacturing the display device DD according to the embodiment of FIG. 3. Hereinafter, the method of manufacturing the display device DD according to the embodiment of FIG. 3 will be described with reference to FIGS. 4 to 11.

Referring to FIG. 4, the circuit element layer CEL, the light emitting element layer LEL, and the encapsulation layer ENC may be formed on the substrate SUB. Components included in the circuit element layer CEL, the light emitting element layer LEL, and the encapsulation layer ENC may be formed by a conventional deposition process, a conventional patterning process (e.g., exposure and development), or the like.

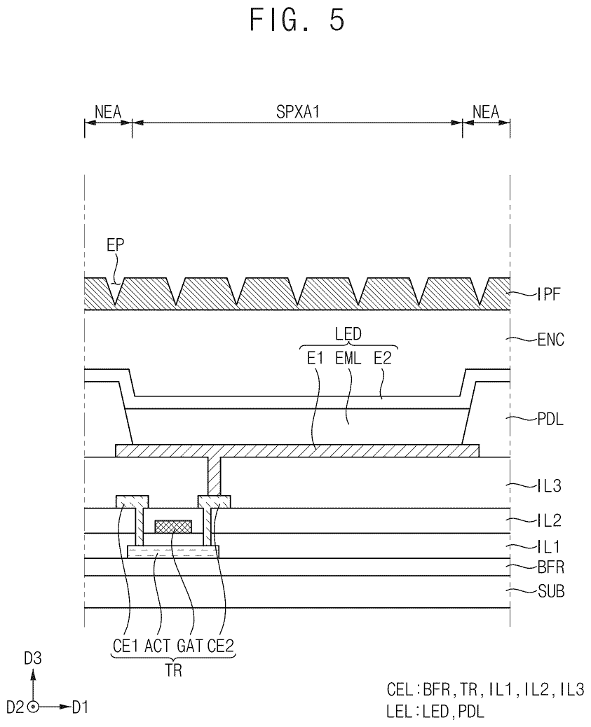

Referring to FIG. 5, the insulating pattern layer IPF may be formed on the encapsulating layer ENC. In an embodiment, the insulating pattern layer IPF may be formed by forming a preliminary insulating pattern layer (not illustrated) on the encapsulating layer ENC and patterning the preliminary insulating pattern layer by exposure and development process. Accordingly, the insulating pattern layer IPF may define the engraved patterns EP recessed from the upper surface of the insulating pattern layer IPF.

The insulating pattern layer IPF may be formed of a material having the first refractive index. That is, the insulating pattern layer IPF may be formed by applying the material having the first refractive index on the encapsulation layer ENC to form the preliminary insulating pattern layer, and patterning the preliminary insulating pattern layer by exposure and development process. Accordingly, the insulating pattern layer IPF may be formed to have the first refractive index. In an embodiment, the insulating pattern layer IPF may be formed of an organic insulating material.

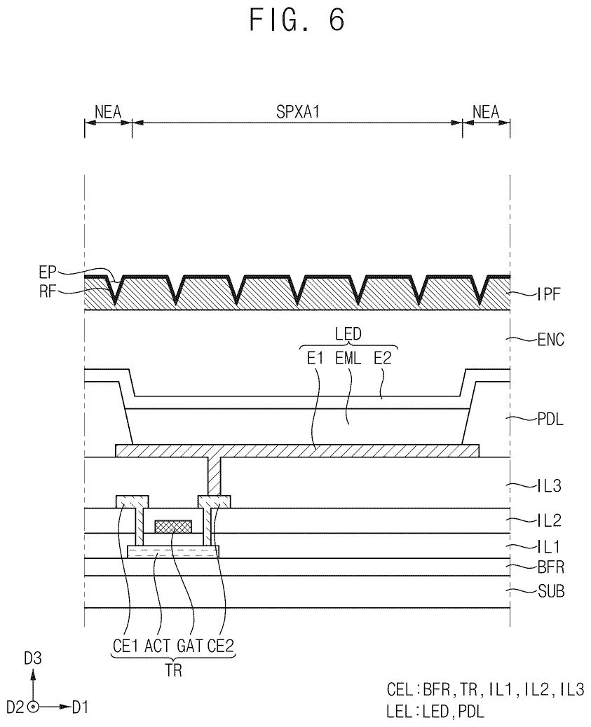

Referring to FIG. 6, a reflective layer RF may be formed on the insulating pattern layer IPF. For example, the reflective layer RF may be formed by a conventional deposition process. The reflective layer RF may be continuously formed on the upper surface of the insulating pattern layer IPF and the inner side surface of the insulating pattern layer IPF defining the engraved patterns EP. The reflective layer RF may be formed of a reflective material. For example, the reflective layer RF may be formed of a metal material. Examples of metal materials that can be used in the reflective layer RF may include Ag, Mg, Al, Pt, Pd, Au, Ni, Nd, Ir, Cr, or the like.

Referring to FIG. 7, the reflective patterns RP (i.e., optical pattern OTP) may be formed by patterning the reflective layer RF. For example, a photoresist pattern (not illustrated) may be formed on the reflective layer RF, and a portion of the reflective layer RF located within the engraved patterns EP may be remained by patterning process using the photoresist pattern as a mask. Accordingly, the reflective patterns RP may be formed. That is, the reflective patterns RP may be disposed within the engraved patterns EP and may include the reflective material. Therefore, the reflective patterns RP may change the path of the light emitted from the light emitting element LED.

In an embodiment, the reflective patterns RP may not be formed on the upper surface of the insulating pattern layer IPF. In this case, after the process of forming the reflective patterns RP, a dummy portion (not illustrated) may remain on the upper surface of the insulating pattern layer IPF. The dummy portion may remain when the reflective layer RF on the upper surface of the insulating pattern layer IPF is not completely removed in the patterning process of the reflective layer RF. That is, the dummy portion may include the same material as the reflective patterns RP. However, embodiments are not limited thereto. If the reflective layer RF on the upper surface of the insulating pattern layer IPF is completely removed, the dummy portion may be omitted.

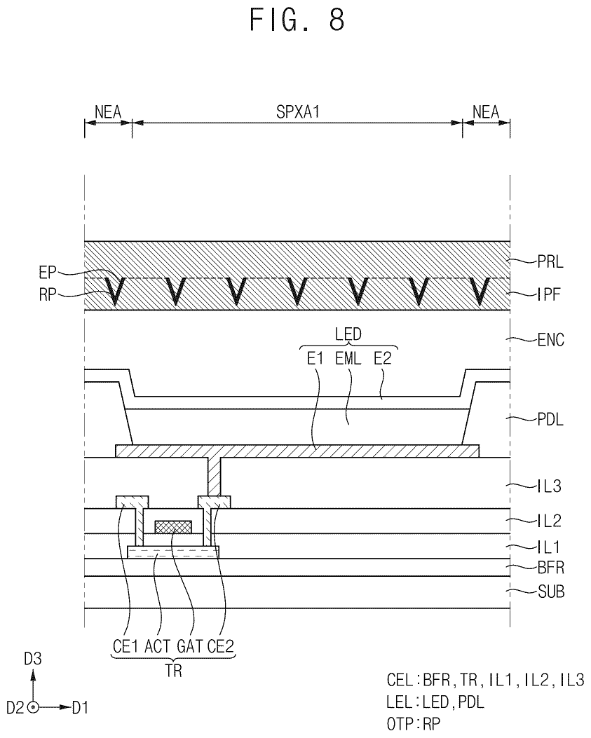

Referring to FIG. 8, a preliminary layer PRL may be formed on the insulating pattern layer IPF and the reflective patterns RP. For example, the preliminary layer PRL may be formed to cover the insulating pattern layer IPF and the reflective patterns RP. That is, the preliminary layer PRL may be formed to fill empty spaces of the engraved patterns EP in which the reflective patterns RP are disposed. The preliminary layer PRL may be formed of a material having the second refractive index. The second refractive index of the preliminary layer PRL may be equal to the first refractive index of the insulating pattern layer IPF. In an embodiment, the preliminary layer PRL may be formed of an organic insulating material.

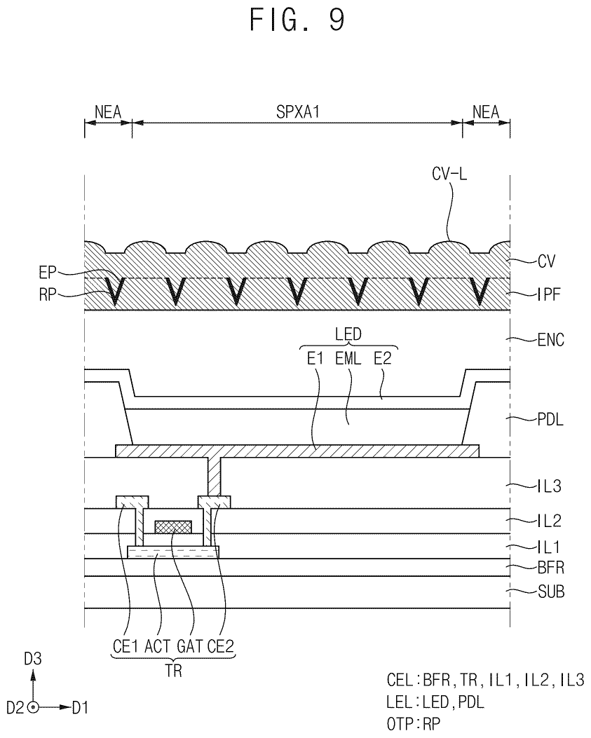

Referring to FIG. 9, the lens patterns CV-L may be formed by patterning the preliminary layer PRL. For example, the lens patterns CV-L may be formed by patterning the preliminary layer PRL using a half-tone mask or the like. Accordingly, the cover layer CV covering the insulating pattern layer IPF and the reflective patterns RP and including the lens patterns CV-L may be formed. As a result, the cover layer CV may be formed to have the second refractive index.

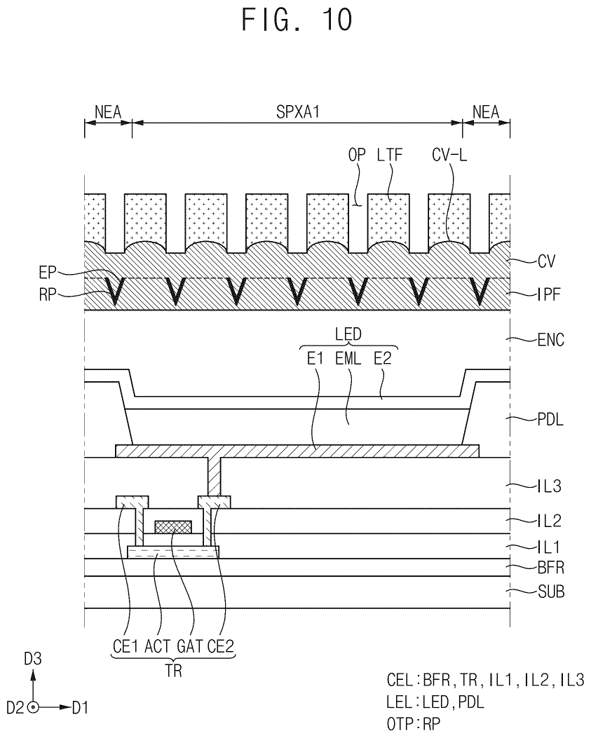

Referring to FIG. 10, the light transmitting layer LTF may be formed on the cover layer CV. In an embodiment, the light transmitting layer LTF may be formed by forming a preliminary light transmitting layer (not illustrated) on the cover layer CV and patterning the preliminary light transmitting layer by exposure and development process. Accordingly, the light transmitting layer LTF may define the openings OP each exposing a portion of the cover layer CV. Specifically, the light transmitting layer LTF may be formed corresponding to the positions where the lens patterns CV-L are disposed. That is, the light transmitting layer LTF may be formed such that the lens patterns CV-L and the openings OP do not overlap each other in the third direction D3.

The light transmitting layer LTF may be formed of a material having the third refractive index. That is, the light transmitting layer LTF may be formed by applying a material having the third refractive index on the cover layer CV to form the preliminary light transmitting layer, and patterning the preliminary light transmitting layer by exposure and development process. Accordingly, the light transmitting layer LTF may be formed to have the third refractive index. The third refractive index may be different from the second refractive index. For example, the third refractive index of the light transmitting layer LTF may be less than the second refractive index of the cover layer CV. In an embodiment, the light transmitting layer LTF may be formed of an organic insulating material.

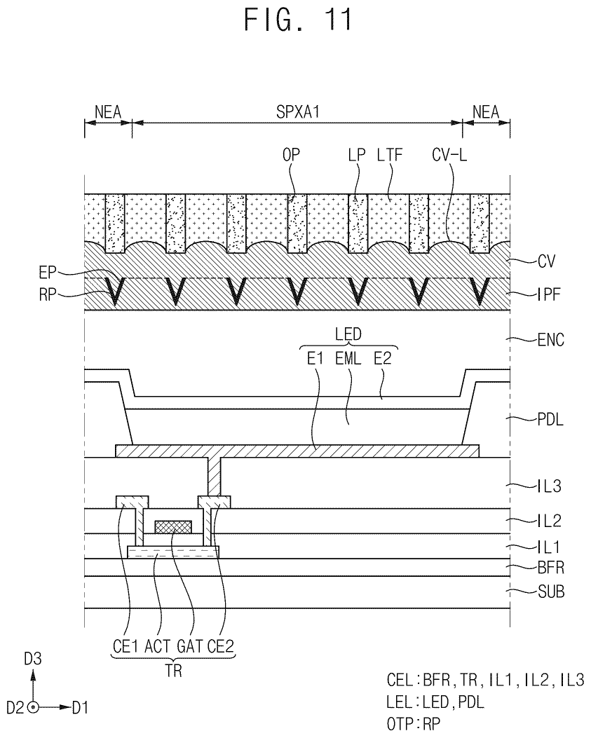

Referring to FIG. 11, the light blocking patterns LP may be formed within the openings OP of the light transmitting layer LTF. For example, the light blocking patterns LP may be filled within the openings OP of the light transmitting layer LTF. Accordingly, the light blocking patterns LP may be formed to overlap the reflective patterns RP (i.e., the optical pattern OTP) in a plan view. The light blocking patterns LP may be formed using a black pigment, a black dye, carbon black, chrome, or the like.

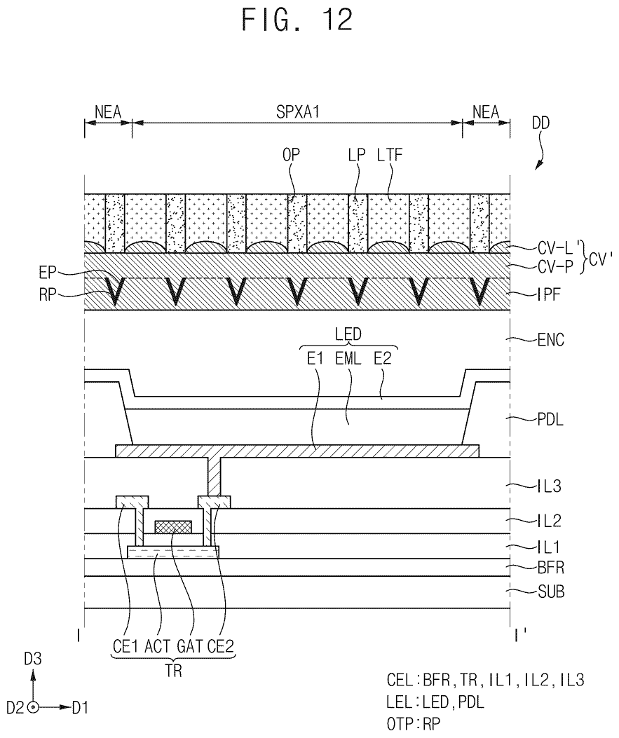

FIG. 12 is a cross-sectional view illustrating another example taken along line I-I′ of FIG. 2.

A display device DD according to an embodiment described below with reference to FIG. 12 may be substantially the same as or similar to the display device DD according to an embodiment described above with reference to FIG. 3 except that the cover layer CV is replaced with a cover layer CV′. In addition, the cover layer CV′ may be substantially the same as or similar to the cover layer CV of FIG. 3 except that the cover layer CV′ has a multi-layer structure including a planarization portion CV-P and lens patterns CV-L′ on the planarization portion CV-P. Therefore, repeated descriptions may be omitted or simplified.

In an embodiment, the cover layer CV′ may have a multi-layer structure including the planarization portion CV-P and the lens patterns CV-L′ on the planarization portion CV-P. That is, the planarization portion CV-P and the lens patterns CV-L′ may be separate components forming an interface.

The planarization portion CV-P may be disposed on the insulating pattern layer IPF and the reflective patterns RP (i.e., the optical pattern OTP). The planarization portion CV-P may cover the reflective patterns RP. For example, the planarization portion CV-P may fill empty spaces of the engraved patterns EP in which the reflective patterns RP are disposed. Accordingly, the cover layer CV′ may cover the reflective patterns RP.

The planarization portion CV-P may include an insulating material. For example, the planarization portion CV-P may include an organic insulating material. Examples of organic insulating materials that can be used as the planarization portion CV-P may include photoresist, polyacrylic resin, polyimide resin, acrylic resin, or the like. These may be used alone or in combination with each other.

The planarization portion CV-P may have the second refractive index. For example, the planarization portion CV-P may be formed of an insulating material having the second refractive index.

The planarization portion CV-P and the insulating pattern layer IPF may include the same material as each other. For example, the planarization portion CV-P and the insulating pattern layer IPF may be formed of the same material. That is, the second refractive index of the planarization portion CV-P may be equal to the first refractive index of the insulating pattern layer IPF. Accordingly, a path of light may not be changed at an interface between the insulating pattern layer IPF and the planarization portion CV-P (i.e., the cover layer CV). The interface between the insulating pattern layer IPF and the planarization portion CV-P (i.e., the cover layer CV) may correspond to the upper surface of the insulating pattern layer IPF.

The lens patterns CV-L′ may be disposed on the planarization portion CV-P. For example, the lens patterns CV-L′ may be formed by applying a preliminary layer on the planarization portion CV-P and patterning the preliminary layer. Each of the lens patterns CV-L′ may include a spherical lens or an aspherical lens.

The lens patterns CV-L′ may be repeatedly arranged. For example, the lens patterns CV-L′ may be repeatedly arranged along the first direction D1. In a plan view, the reflective patterns RP (i.e., the optical pattern OTP) may be disposed between the lens patterns CV-L′. That is, the lens patterns CV-L′ may not overlap the reflective patterns RP (i.e., the optical pattern OTP) in the third direction D3. For example, the lens patterns CV-L′ and the reflective patterns RP may be alternately arranged with each other.

The lens patterns CV-L′ may be located on the path of the light changed by the reflective patterns RP (i.e., the optical pattern OTP). That is, a reflected light obtained by the light emitted from the light emitting element LED being reflected by the reflective patterns RP may be provided to the lens patterns CV-L′.

The lens patterns CV-L′ may have the second refractive index. For example, the lens patterns CV-L′ may be formed of an insulating material having the second refractive index. That is, the lens patterns CV-L′ and the planarization portion CV-P may include the same material as each other. For example, the lens patterns CV-L′ and the planarization portion CV-P may be formed of the same material. Accordingly, a path of light may not be changed at an interface between the lens patterns CV-L′ and the planarization portion CV-P.

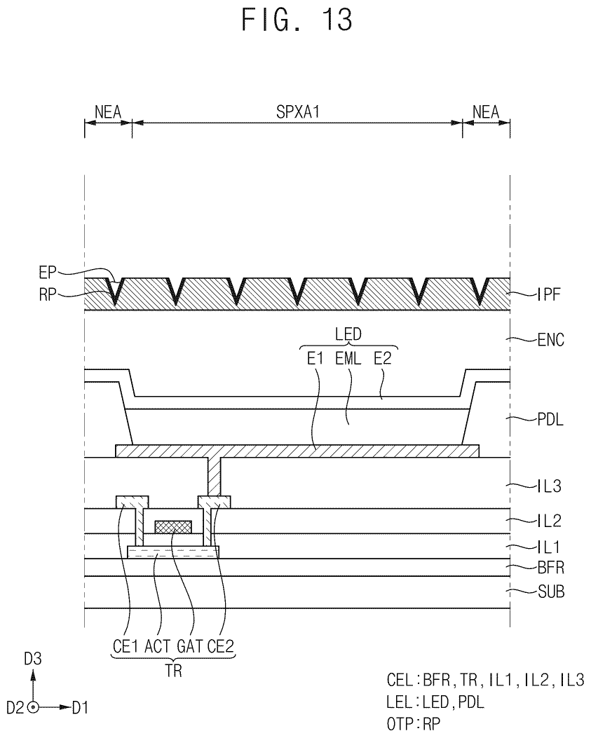

FIGS. 13 to 16 are views illustrating a method of manufacturing a display device according to an embodiment.

Specifically, FIGS. 13 to 16 are views for describing a method of manufacturing the display device DD according to the embodiment of FIG. 12. Hereinafter, the method of manufacturing the display device DD according to the embodiment of FIG. 12 will be described with reference to FIGS. 13 to 16.

Referring to FIG. 13, the circuit element layer CEL, the light emitting element layer LEL, the encapsulation layer ENC, the insulating pattern layer IPF, and the reflective patterns RP (i.e., the optical pattern OTP) may be formed on the substrate SUB. A detailed description thereof will be omitted as it overlaps the description above with reference to FIGS. 4 to 7.

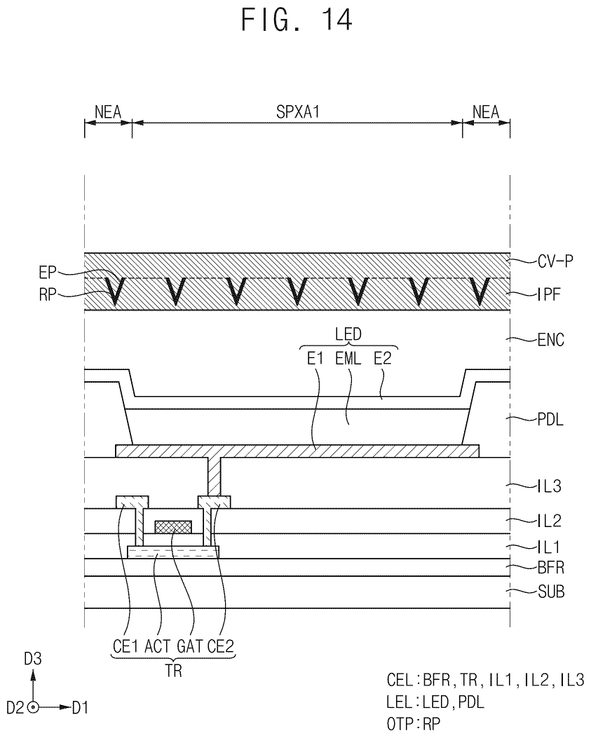

Referring to FIG. 14, the planarization portion CV-P may be formed on the insulating pattern layer IPF and the reflective patterns RP. For example, the planarization portion CV-P may be formed to cover the insulating pattern layer IPF and the reflective patterns RP (i.e., the optical pattern OTP). That is, the planarization portion CV-P may be formed to fill empty spaces of the engraved patterns EP in which the reflective patterns RP are disposed. The planarization portion CV-P may be formed of a material having the second refractive index. The second refractive index of the planarization portion CV-P may be equal to the first refractive index of the insulating pattern layer IPF. In an embodiment, the planarization portion CV-P may be formed of an organic insulating material.

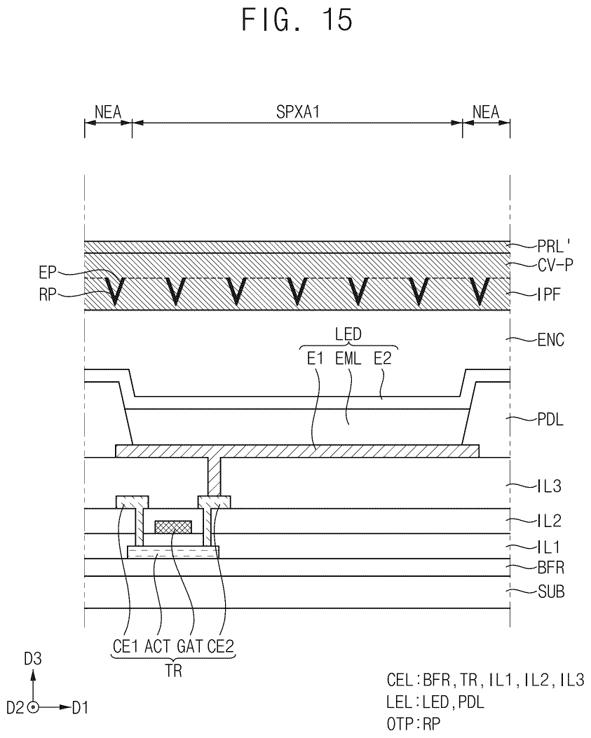

Referring to FIG. 15, a preliminary layer PRL′ may be formed on the planarization portion CV-P. The preliminary layer PRL′ may be formed of a material having the second refractive index. In an embodiment, the preliminary layer PRL′ may be formed of an organic insulating material.

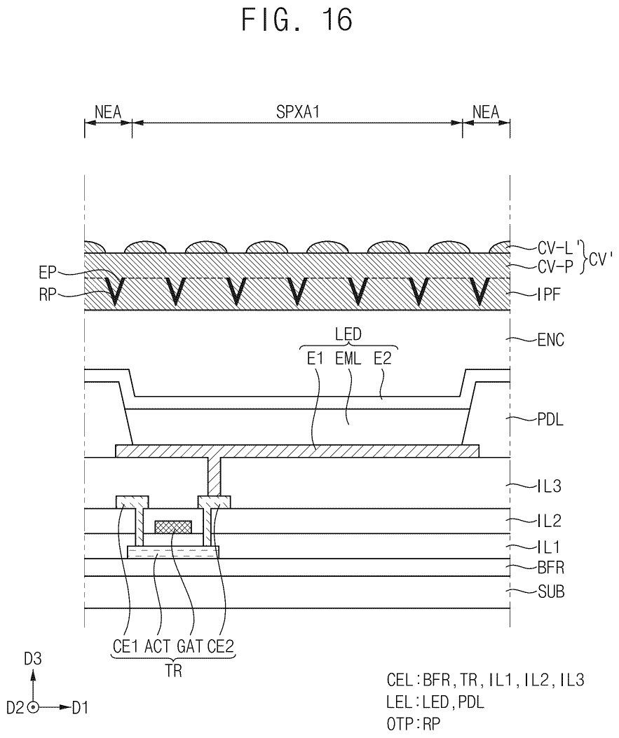

Referring to FIG. 16, the lens patterns CV-L′ may be formed by patterning the preliminary layer PRL′. For example, the lens patterns CV-L′ may be formed by patterning the preliminary layer PRL′ using a mask or the like. Accordingly, the cover layer CV′ covering the insulating pattern layer IPF and the reflective patterns RP and including the planarization portion CV-P and the lens patterns CV-L′ may be formed. As a result, the cover layer CV′ may be formed to cover the insulating pattern layer IPF and the reflective patterns RP and have the second refractive index.

Thereafter, as illustrated in FIG. 12, the light transmitting layer LTF and the light blocking patterns LP may be formed on the cover layer CV′. A detailed description thereof will be omitted as it overlaps the description above with reference to FIGS. 10 and 11.

That is, according to the method of manufacturing the display device DD described with reference to FIGS. 13 to 16, the cover layer CV′ may be formed by forming the planarization portion CV-P and the lens patterns CV-L′ by separate processes.

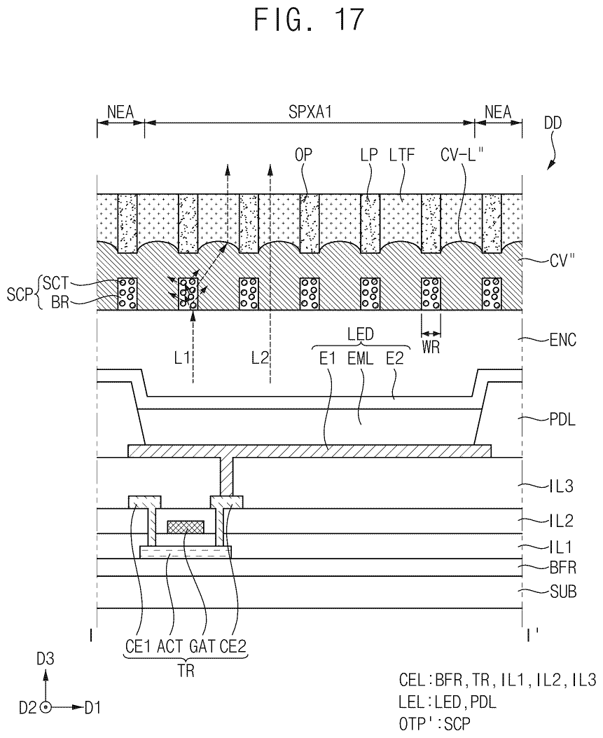

FIG. 17 is a cross-sectional view illustrating still another example taken along line I-I′ of FIG. 2.

A display device DD according to an embodiment described below with reference to FIG. 17 may include a substrate SUB, a circuit element layer CEL, a light emitting element layer LEL, an encapsulation layer ENC, an optical pattern OTP′, a cover layer CV″, a light transmitting layer LTF, and light blocking patterns LP. The descriptions above with reference to FIG. 3 may be equally applied to the descriptions of the substrate SUB, the circuit element layer CEL, the light emitting element layer LEL, the encapsulation layer ENC, the light transmitting layer LTF, and the light blocking patterns LP. Therefore, repeated descriptions may be omitted or simplified.

The optical pattern OTP′ may be disposed on the encapsulation layer ENC. The optical pattern OTP′ may change a path of the light emitted from the light emitting element LED. For example, a path of some of the light emitted from the light emitting element LED that arrives at the optical pattern OTP′ may be changed by the optical pattern OTP′.

In an embodiment, the optical pattern OTP′ may include scattering patterns SCP. For example, the optical pattern OTP′ may be a set of the scattering patterns SCP. Each of the scattering patterns SCP may include a base resin BR and scatterers SCT.

The scatterers SCT may change a path of an incident light, which is incident to the scattering patterns SCP, by scattering the incident light without substantially changing a wavelength of the incident light. Each of the scatterers SCT may include a metal oxide or an organic material.

The scatterers SCT may be disposed within the base resin BR. For example, the base resin BR may include epoxy resin, acrylic resin, phenol resin, melamine resin, cardo resin, imide resin, or the like.

The scattering patterns SCP may change the path of the some of the light emitted from the light emitting element LED that arrives at the scattering patterns SCP. Specifically, light provided to the scattering patterns SCP while traveling in the third direction D3 may be scattered by the scattering patterns SCP (specifically, by the scatterers SCT) to travel in a direction other than the third direction D3.

A shape of each of the scattering patterns SCP illustrated in FIG. 17 is an example and the shape may be variously changed or modified.

In addition, although not illustrated, in an embodiment, additional functional layers may be disposed between the encapsulation layer ENC and the scattering patterns SCP (i.e., the optical pattern OTP′). For example, a sensing layer for detecting an external touch may be disposed between the encapsulation layer ENC and the scattering patterns SCP (i.e., the optical pattern OTP′).

The cover layer CV″ may be disposed on the encapsulation layer ENC and the scattering patterns SCP (i.e., the optical pattern OTP′). The cover layer CV″ may cover the scattering patterns SCP.

The cover layer CV″ may include an insulating material. For example, the cover layer CV″ may include an organic insulating material. Examples of organic insulating materials that can be used as the cover layer CV″ may include photoresist, polyacryl-based resin, polyimide-based resin, acrylic-based resin, or the like. These may be used alone or in combination with each other.

The cover layer CV″ may have the second refractive index. For example, the cover layer CV″ may be formed of an insulating material having the second refractive index.

The cover layer CV″ may include lens patterns CV-L″. In an embodiment, the lens patterns CV-L″ may be defined by a concave-convex structure of an upper surface of the cover layer CV″. For example, the cover layer CV″ including the lens patterns CV-L″ may be formed by applying a preliminary layer on the encapsulation layer ENC and the optical pattern OTP′, and patterning the preliminary layer using a half-tone mask or the like. However, embodiments are not limited thereto. Each of the lens patterns CV-L″ may include a spherical lens or an aspherical lens in another embodiment.

The lens patterns CV-L″ may be repeatedly arranged. For example, the lens patterns CV-L″ may be repeatedly arranged along the first direction D1. In a plan view, the scattering patterns SCP (i.e., the optical pattern OTP′) may be disposed between the lens patterns CV-L″. That is, the lens patterns CV-L″ may not overlap the scattering patterns SCP (i.e., the optical pattern OTP′) in the third direction D3. For example, the lens patterns CV-L″ and the scattering patterns SCP may be alternately arranged with each other.

The lens patterns CV-L″ may be located on the path of the light changed by the scattering patterns SCP (i.e., the optical pattern OTP′). That is, a scattered light obtained by the light emitted from the light emitting element LED being scattered by the scattering patterns SCP may be provided to the lens patterns CV-L″.

Similarly to the description described above with reference to FIG. 3, the light transmitting layer LTF may be disposed corresponding to the positions where the lens patterns CV-L″ are disposed, and may cover the lens patterns CV-L″. In addition, the light transmitting layer LTF may have the third refractive index less than the second refractive index of the cover layer CV″.

In addition, similarly to the reflective patterns RP (i.e., the optical pattern OTP) described above with reference to FIG. 3, the light blocking patterns LP may overlap the scattering patterns SCP (i.e., the optical pattern OTP′) in a plan view. That is, one of the light blocking patterns LP may overlap a corresponding one of the scattering patterns SCP in the third direction D3. That is, the light blocking patterns LP and the scattering patterns SCP may correspond to each other one by one.

As a result, an incident light emitted from the light emitting element LED and traveling in the third direction D3 toward the light blocking patterns LP may be provided to the scattering patterns SCP (i.e., the optical pattern OTP′) before arriving at the light blocking patterns LP. The incident light provided to the scattering patterns SCP may be scattered by the scattering patterns SCP and may travel in a direction other than the third direction D3. Accordingly, a scattered light obtained by the incident light being scattered by the scattering patterns SCP may travel between the light blocking patterns LP.

In addition, the scattered light may be provided to the interface between the light transmitting layer LTF and the lens patterns CV-L″. The scattered light provided to the interface may be refracted due to the difference in refractive indices between the light transmitting layer LTF and the cover layer CV″ and/or shapes of the lens patterns CV-L″ and may travel in the third direction D3 again. That is, a refracted light obtained by the scattered light being refracted at the interface may travel in the third direction D3 and may be emitted to the outside through the light transmitting layer LTF. Therefore, according to embodiments, a loss of the light, which is emitted from the light emitting element LED and travels in the third direction D3, due to the light blocking patterns LP may be reduced or prevented. Accordingly, a front light transmittance of the display device DD may be reduced, and a light efficiency of the display device DD may be reduced.

For example, a path of a first incident light L1 traveling in the third direction D3 toward the light blocking patterns LP may be changed by the scattering patterns SCP (i.e., the optical pattern OTP′) and the lens patterns CV-L″. Therefore, the first incident light L1 may not be blocked by the light blocking patterns LP and may be emitted to the outside through the light transmitting layer LTF while traveling in the third direction D3. That is, the first incident light L1 may not be lost. For this, in an embodiment, a shape and an area of the scattering pattern SCP may be the same as a shape and an area of a corresponding light blocking pattern LP such that the scattering pattern SCP completely overlaps the corresponding light blocking pattern LP in a plan view. For example, a width WS of the scattering pattern SCP may be the same as the width WD of the corresponding light blocking pattern LP measured in the same direction (e.g., the first direction DR1.)

Meanwhile, a second incident light L2 may not be affected by the scattering patterns SCP. That is, the scattering patterns SCP may not be located on a path of the second incident light L2. For example, the second incident light L2 may travel between the scattering patterns SCP. Accordingly, the second incident light L2 may travel in the third direction D3 without substantially changing the path and may be emitted to the outside through the light transmitting layer LTF.

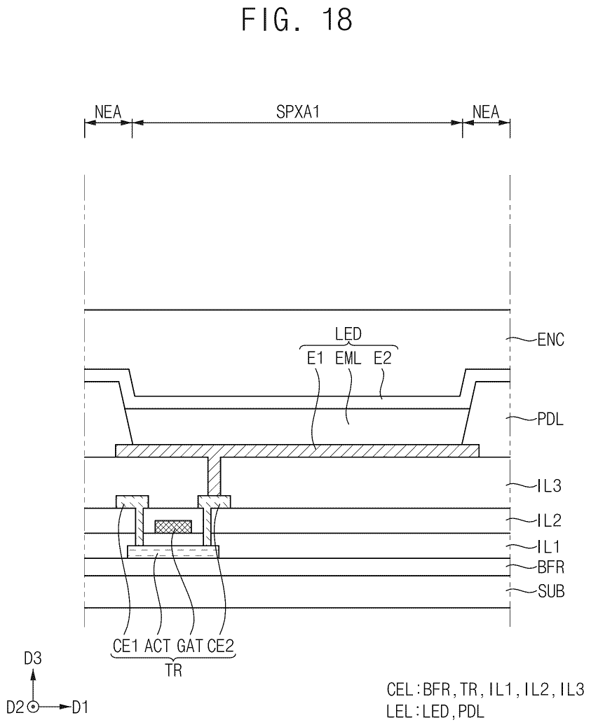

FIGS. 18 to 21 are views illustrating a method of manufacturing a display device according to an embodiment.

Specifically, FIGS. 18 to 21 are views for describing a method of manufacturing the display device DD according to the embodiment of FIG. 17. Hereinafter, the method of manufacturing the display device DD according to the embodiment of FIG. 17 will be described with reference to FIGS. 18 to 21.

Referring to FIG. 18, the circuit element layer CEL, the light emitting element layer LEL, and the encapsulation layer ENC may be formed on the substrate SUB. Components included in the circuit element layer CEL, the light emitting element layer LEL, and the encapsulation layer ENC may be formed by a conventional deposition process, a conventional patterning process (e.g., exposure and development), or the like.

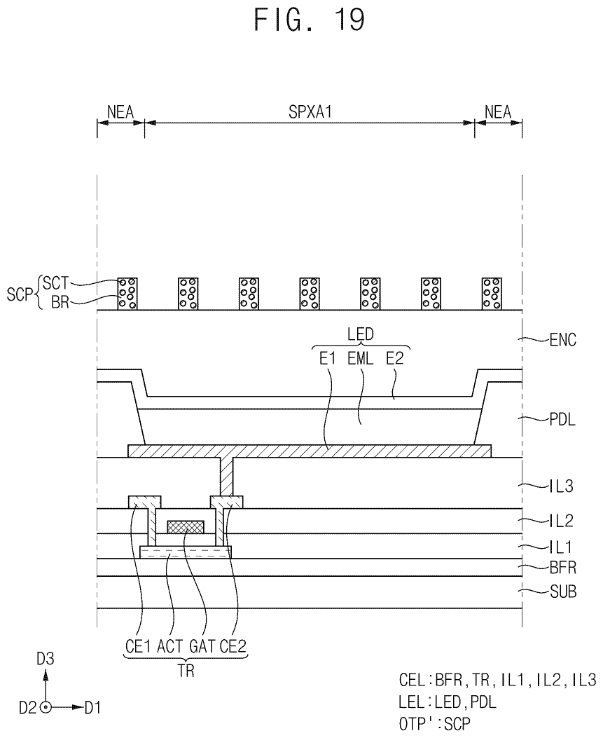

Referring to FIG. 19, the scattering patterns SCP (i.e., the optical pattern OTP′) may be formed on the encapsulation layer ENC. In an embodiment, the scattering patterns SCP may be formed by forming a scattering layer (not illustrated) including the scatterers SCT and the base resin BR on the encapsulation layer ENC, and patterning the scattering layer by exposure and development process.

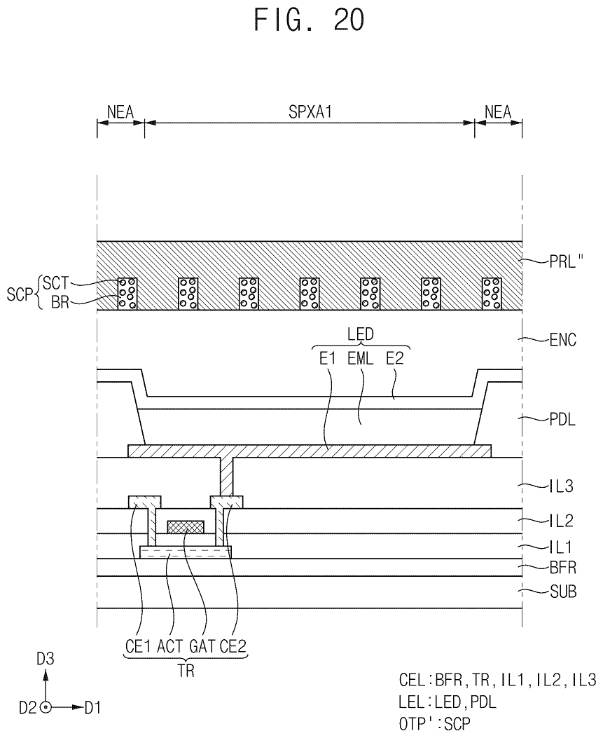

Referring to FIG. 20, a preliminary layer PRL″ may be formed on the encapsulation layer ENC and the scattering patterns SCP. For example, the preliminary layer PRL″ may be formed to cover the scattering patterns SCP (i.e., the optical pattern OTP′). The preliminary layer PRL″ may be formed of a material having the second refractive index. The preliminary layer PRL″ may be formed of an organic insulating material.

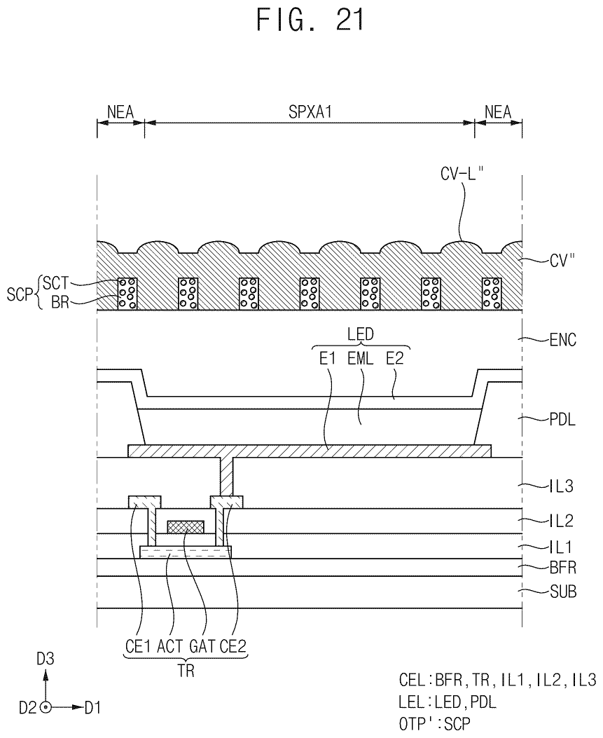

Referring to FIG. 21, the lens patterns CV-L″ may be formed by patterning the preliminary layer PRL″. For example, the lens patterns CV-L″ may be formed by patterning the preliminary layer PRL″ using a half-tone mask or the like. Accordingly, the cover layer CV″ covering the scattering patterns SCP and including the lens patterns CV-L″ may be formed. As a result, the cover layer CV″ may be formed to have the second refractive index.

Thereafter, as illustrated in FIG. 17, the light transmitting layer LTF and the light blocking patterns LP may be formed on the cover layer CV″. A detailed description thereof will be omitted as it overlaps the description above with reference to FIGS. 10 and 11.

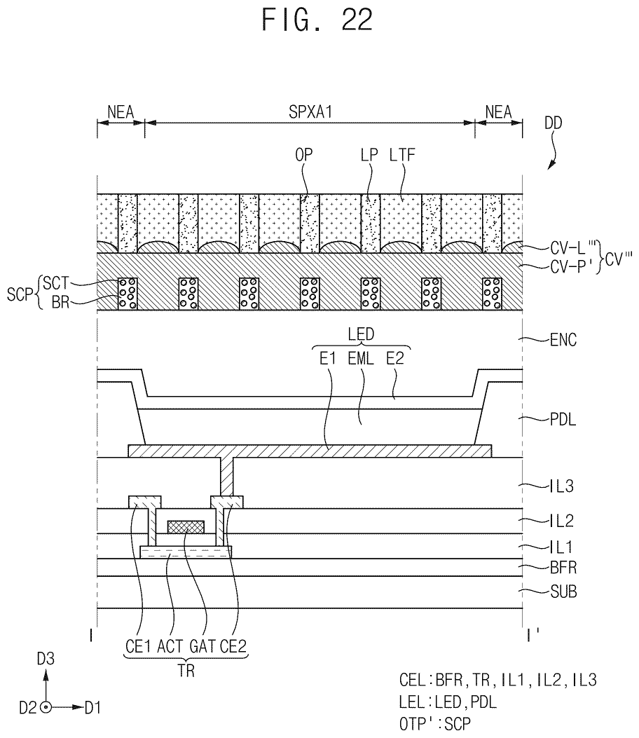

FIG. 22 is a cross-sectional view illustrating yet another example taken along line I-I′ of FIG. 2.

A display device DD according to an embodiment described below with reference to FIG. 22 may be substantially the same as or similar to the display device DD according to an embodiment described above with reference to FIG. 17 except that the cover layer CV″ is replaced with a cover layer CV″′. In addition, the cover layer CV″′ may be substantially the same as or similar to the cover layer CV″ of FIG. 17 except that the cover layer CV″′ has a multi-layer structure including a planarization portion CV-P′ and lens patterns CV-L″′ on the planarization portion CV-P′. Therefore, repeated descriptions may be omitted or simplified.

In an embodiment, the cover layer CV″′ may have a multi-layer structure including the planarization portion CV-P′ and the lens patterns CV-L″′ on the planarization portion CV-P′. That is, the planarization portion CV-P′ and the lens patterns CV-L″′ may be separate components forming an interface.

The planarization portion CV-P′ may be disposed on the encapsulation layer ENC and the scattering patterns SCP (i.e., the optical pattern OTP′). The planarization portion CV-P′ may cover the scattering patterns SCP.

The planarization portion CV-P′ may include an insulating material. For example, the planarization portion CV-P′ may include an organic insulating material. Examples of organic insulating materials that can be used as the planarization portion CV-P′ may include photoresist, polyacrylic resin, polyimide resin, acrylic resin, or the like. These may be used alone or in combination with each other.

The planarization portion CV-P′ may have the second refractive index. For example, the planarization portion CV-P′ may be formed of an insulating material having the second refractive index.

The lens patterns CV-L″′ may be disposed on the planarization portion CV-P′. For example, the lens patterns CV-L″′ may be formed by applying a preliminary layer on the planarization portion CV-P′ and patterning the preliminary layer. Each of the lens patterns CV-L″′ may include a spherical lens or an aspherical lens.

The lens patterns CV-L″′ may be repeatedly arranged. For example, the lens patterns CV-L″′ may be repeatedly arranged along the first direction D1. In a plan view, the scattering patterns SCP (i.e., the optical pattern OTP′) may be disposed between the lens patterns CV-L″′. That is, the lens patterns CV-L″′ may not overlap the scattering patterns SCP (i.e., the optical pattern OTP′) in the third direction D3. For example, the lens patterns CV-L″′ and the scattering patterns SCP may be alternately arranged with each other.

The lens patterns CV-L″′ may be located on the path of the light changed by the scattering patterns SCP (i.e., the optical pattern OTP′). That is, a scattered light obtained by the light emitted from the light emitting element LED being scattered by the scattering patterns SCP may be provided to the lens patterns CV-L″′.

The lens patterns CV-L″′ may have the second refractive index. For example, the lens patterns CV-L″′ may be formed of an insulating material having the second refractive index. That is, the lens patterns CV-L″′ and the planarization portion CV-P′ may include the same material as each other. For example, the lens patterns CV-L″′ and the planarization portion CV-P′ may be formed of the same material. Accordingly, a path of light may not be changed at an interface between the lens patterns CV-L″′ and the planarization portion CV-P′.

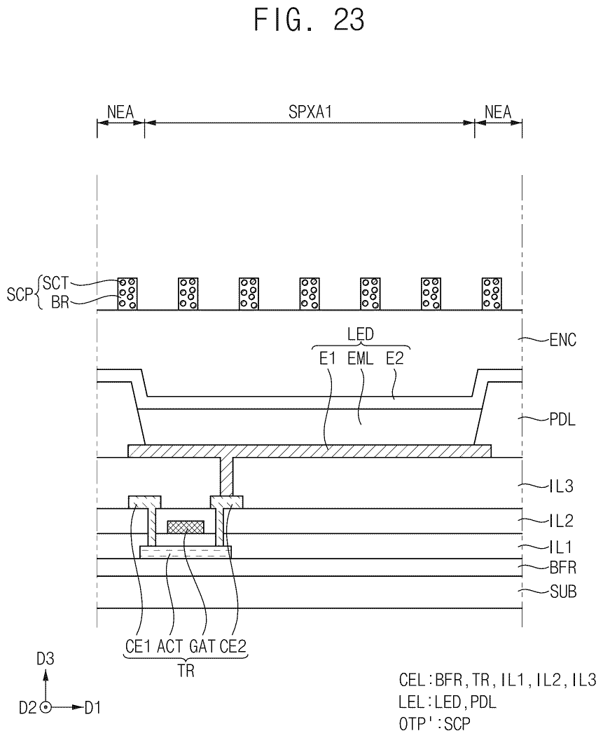

FIGS. 23 to 26 are views illustrating a method of manufacturing a display device according to an embodiment.

Specifically, FIGS. 23 to 26 are views for describing a method of manufacturing the display device DD according to the embodiment of FIG. 22. Hereinafter, the method of manufacturing the display device DD according to the embodiment of FIG. 22 will be described with reference to FIGS. 23 to 26.

Referring to FIG. 23, the circuit element layer CEL, the light emitting element layer LEL, the encapsulation layer ENC, and the scattering patterns SCP (i.e., the optical pattern OTP′) may be formed on the substrate SUB. A detailed description thereof will be omitted as it overlaps the description above with reference to FIGS. 18 and 19.

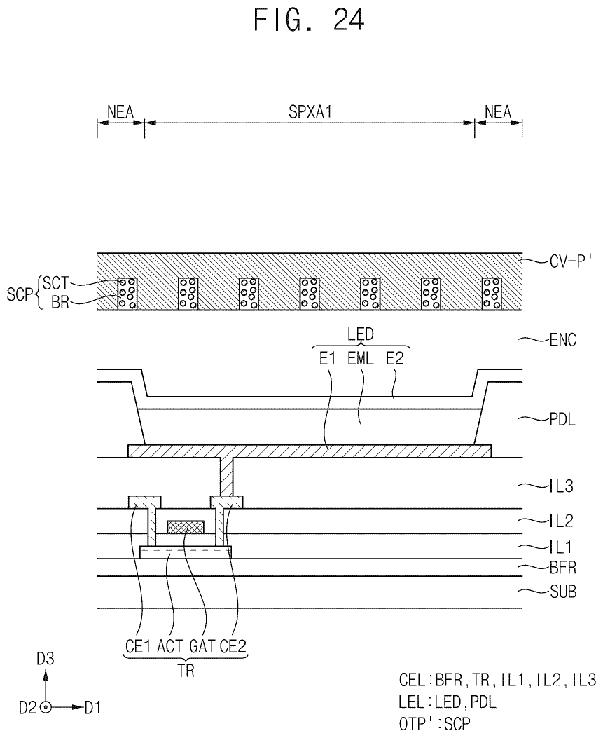

Referring to FIG. 24, the planarization portion CV-P′ may be formed on the encapsulation layer ENC and the scattering patterns SCP. For example, the planarization portion CV-P′ may be formed to cover the scattering patterns SCP (i.e., the optical pattern OTP′). The planarization portion CV-P′ may be formed of a material having the second refractive index. In an embodiment, the planarization portion CV-P′ may be formed of an organic insulating material.

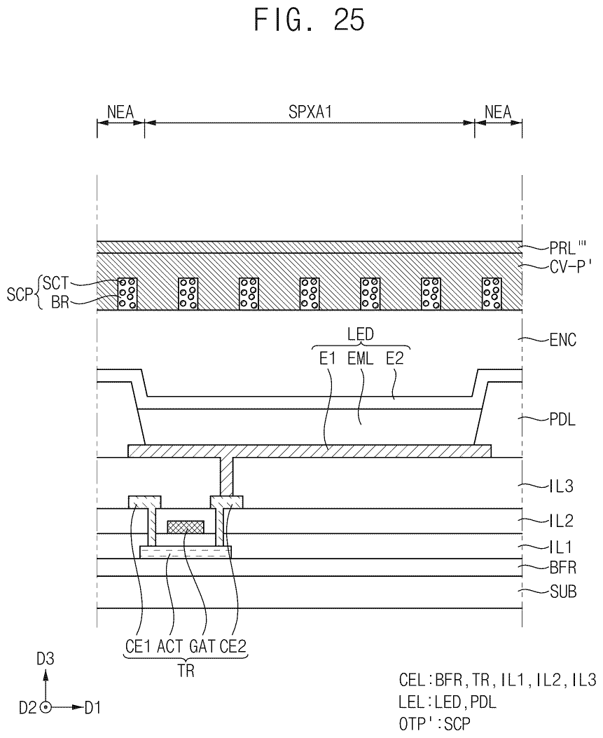

Referring to FIG. 25, a preliminary layer PRL″′ may be formed on the planarization portion CV-P′. The preliminary layer PRL″′ may be formed of a material having the second refractive index. In an embodiment, the preliminary layer PRL″′ may be formed of an organic insulating material.

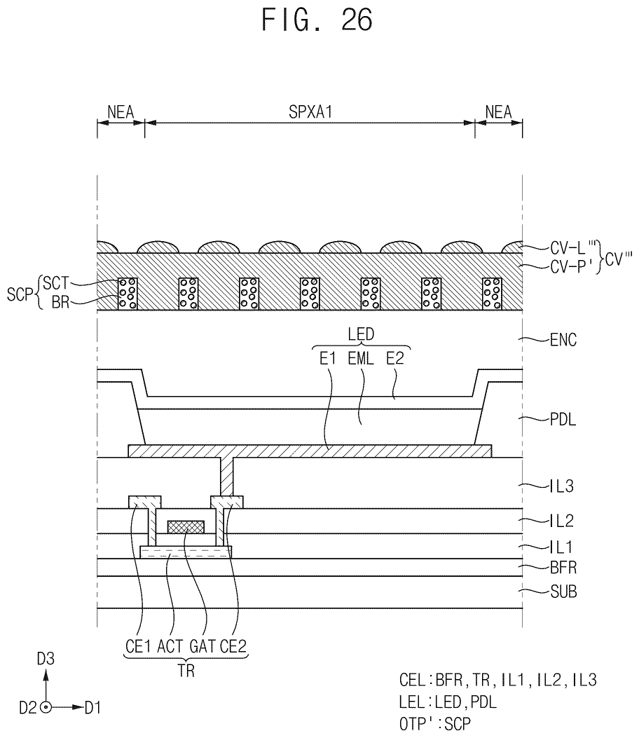

Referring to FIG. 26, the lens patterns CV-L″′ may be formed by patterning the preliminary layer PRL″′. For example, the lens patterns CV-L″′ may be formed by patterning the preliminary layer PRL″′ using a mask or the like. Accordingly, the cover layer CV″′ covering the scattering patterns SCP and including the planarization portion CV-P′ and the lens patterns CV-L″′ may be formed. As a result, the cover layer CV″′ may be formed to cover the scattering patterns SCP (i.e., the optical pattern OTP′) and have the second refractive index.

Thereafter, as illustrated in FIG. 22, the light transmitting layer LTF and the light blocking patterns LP may be formed on the cover layer CV″′. A detailed description thereof will be omitted as it overlaps the description above with reference to FIGS. 10 and 11.

That is, according to the method of manufacturing the display device DD described with reference to FIGS. 23 to 26, the cover layer CV″′ may be formed by forming the planarization portion CV-P′ and the lens patterns CV-L″′ by separate processes.

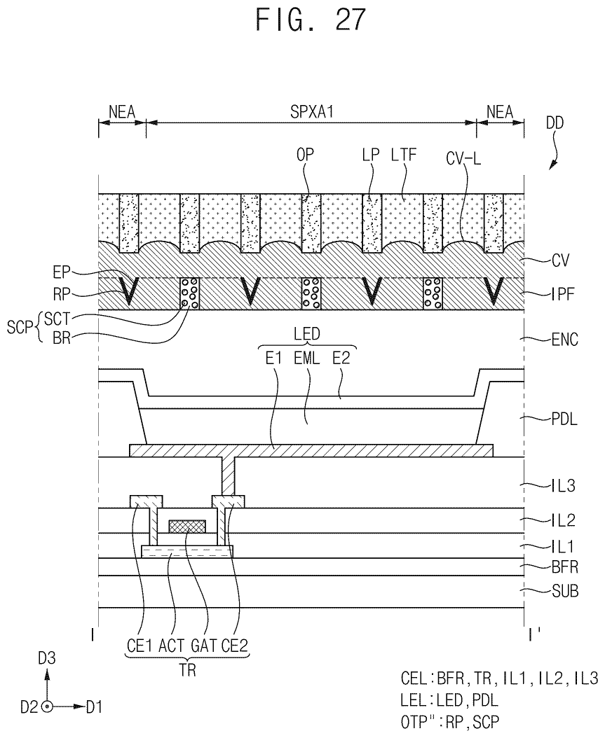

FIG. 27 is a cross-sectional view illustrating still another example taken along line I-I′ of FIG. 2.

A display device DD according to an embodiment described below with reference to FIG. 27 may be substantially the same as or similar to the display device DD according to an embodiment described above with reference to FIG. 3 except that the optical pattern OTP is replaced with a optical pattern OTP″. In addition, the optical pattern OTP″ may be substantially the same as or similar to the optical pattern OTP of FIG. 3 except that the optical pattern OTP″ is a set of reflective patterns RP and scattering patterns SCP. Therefore, repeated descriptions may be omitted or simplified.

In an embodiment, the optical pattern OTP″ may include the reflective patterns RP and the scattering patterns SCP. For example, the optical pattern OTP″ may be a set of the reflective patterns RP and the scattering patterns SCP. In this case, the reflective patterns RP may be disposed within the engraved patterns EP of the insulating pattern layer IPF, and the scattering patterns SCP may be covered by the insulating pattern layer IPF. However, embodiments are not limited thereto.

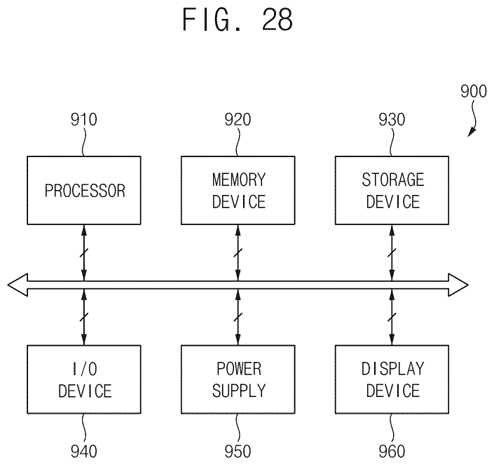

FIG. 28 is a block diagram illustrating an electronic device according to an embodiment.

Referring to FIG. 28, in an embodiment, an electronic device 900 may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although embodiments and implementations have been described herein, other embodiments and modifications will be apparent from this description. Accordingly, the invention is not limited to such embodiments, but rather to the broader scope of the appended claims and various obvious modifications and equivalent arrangements as would be apparent to a person of ordinary skill in the art.

What is claimed is:

1. A display device comprising:
a light emitting element layer including a light emitting element configured to emit light;
an optical pattern disposed on the light emitting element layer and configured to change a path of the light emitted from the light emitting element;
a cover layer covering the optical pattern and having a first refractive index;
a light transmitting layer disposed on the cover layer, having a second refractive index different from the first refractive index, and defining openings each exposing a portion of the cover layer; and
light blocking patterns disposed within the openings on the cover layer and overlapping the optical pattern in a plan view.

2. The display device of claim 1, wherein the first refractive index is greater than the second refractive index.

3. The display device of claim 1, wherein the cover layer includes a plurality of lens patterns repeatedly arranged.

4. The display device of claim 3, wherein the lens patterns are located on the path of the light changed by the optical pattern.

5. The display device of claim 3, wherein the light transmitting layer covers the lens patterns.

6. The display device of claim 3, wherein the optical pattern is disposed between the lens patterns in the plan view.

7. The display device of claim 3, wherein the light blocking patterns and the lens patterns are alternately arranged with each other.

8. The display device of claim 1, wherein the optical pattern includes reflective patterns including a reflective material and configured to reflect the light emitted from the light emitting element.

9. The display device of claim 8, further comprising:
an insulating pattern layer, which is entirely covered by the cover layer and the reflective patterns and has a third refractive index greater than the second refractive index.

10. The display device of claim 9, wherein the insulating pattern layer and the cover layer include a same material as each other, and
wherein the first refractive index and the third refractive index are equal to each other.

11. The display device of claim 9, wherein the insulating pattern layer defines engraved patterns therein, and
wherein the reflective patterns are disposed within the engraved patterns.

12. The display device of claim 11, wherein the cover layer is disposed to fill an empty space of the engraved patterns in which the reflective patterns are disposed.

13. The display device of claim 1, wherein the optical pattern includes scattering patterns including scatterers configured to scatter the light emitted from the light emitting element.

14. A method of manufacturing a display device, the method comprising:
forming a light emitting element layer on a substrate, the light emitting element layer including a light emitting element configured to emit light;
forming an optical pattern on the light emitting element layer, wherein the optical pattern is configured to change a path of the light emitted from the light emitting element;
forming a cover layer covering the optical pattern and having a first refractive index;
forming a light transmitting layer on the cover layer, the light transmitting layer having a second refractive index different from the first refractive index and defining openings each exposing a portion of the cover layer; and
forming light blocking patterns within the openings on the cover layer, the light blocking patterns overlapping the optical pattern in a plan view.

15. The method of claim 14, wherein the first refractive index is greater than the second refractive index.

16. The method of claim 14, wherein the forming of the cover layer includes:
forming a preliminary layer having the first refractive index; and
patterning the preliminary layer to form a plurality of lens patterns repeatedly arranged, and
wherein the light transmitting layer is formed to cover the lens patterns.

17. The method of claim 14, further comprising:
before the forming of the optical pattern, forming an insulating pattern layer on the light emitting element layer, the insulating pattern layer having a third refractive index greater than the second refractive index and defining engraved patterns therein, and
wherein the forming of the optical pattern includes forming the optical pattern within the engraved patterns by forming a reflective layer including a reflective material on the insulating pattern layer and patterning the reflective layer.

18. The method of claim 17, wherein the insulating pattern layer and the cover layer are formed of a same material, and
wherein the first refractive index and the third refractive index are equal to each other.

19. The method of claim 17, wherein the cover layer is formed to cover both the insulating pattern layer and the optical pattern.

20. The method of claim 14, wherein the forming of the optical pattern includes forming a scattering layer including scatterers on the light emitting element layer and patterning the scattering layer.

21. An electronic device comprising:
a display device; and
a power supply configured to provide power to the display device,
wherein the display device comprises:
a light emitting element layer including a light emitting element configured to emit light;
an optical pattern disposed on the light emitting element layer and configured to change a path of the light emitted from the light emitting element;
a cover layer covering the optical pattern and having a first refractive index;
a light transmitting layer disposed on the cover layer, having a second refractive index different from the first refractive index, and defining openings each exposing a portion of the cover layer; and
light blocking patterns disposed within the openings on the cover layer and overlapping the optical pattern in a plan view.
